(19) United States
(12) Patent Application Publication
(10) Pub. No.: US 2026/0182645 A1
(43) Pub. Date: Jul. 2, 2026

(54) AEROSOL GENERATING DEVICE

(71) Applicant: KT&G CORPORATION, Daejeon (KR)

(72) Inventors: Hanyong LEE, Daejeon (KR); Jungho KIM, Daejeon (KR); Seowon SONG, Daejeon (KR); Younji SHIN, Daejeon (KR); Byungsung CHO, Daejeon (KR)

(73) Assignee: KT&G CORPORATION, Daejeon (KR)

(21) Appl. No.: 19/332,481

(22) Filed: Sep. 18, 2025

(30) Foreign Application Priority Data
Dec. 30, 2024 (KR) 10-2024-0201128

(51) Int. Cl. A24F 40/46; A24F 40/51

(52) U.S. Cl. CPC A24F 40/46; A24F 40/51

(57) ABSTRACT

An aerosol generating device includes a source unit configured to generate microwaves, a resonating unit including an accommodation space for accommodating an aerosol generating article and configured to generate microwave resonance due to the microwaves generated by the source unit, a cover arranged in the resonating unit to move between an opening position to open the accommodation space and a closing position to close the accommodation space, and a control unit configured to control the source unit based on an external force applied by the aerosol generating article to the cover.

### CROSS-REFERENCE TO RELATED APPLICATION

This application is based on and claims priority under 35 U.S.C. § 119 to Korean Patent Application No. 10-2024-0201128, filed on Dec. 30, 2024, in the Korean Intellectual Property Office, the disclosure of which is incorporated by reference herein in its entirety.

### BACKGROUND

### 1. Field

Embodiments relate to an aerosol generating device capable of generating aerosols by heating an aerosol generating article by using a dielectric heating method.

2. Description of the Related Art

Recently, there has been an increasing demand for an alternative method of overcoming the disadvantages of normal cigarettes. For example, there is an increasing demand for a system for generating aerosols by heating an aerosol generating substrate by using an aerosol generating device, rather than by burning cigarettes.

Generally, aerosol generating devices may generate aerosols by heating an aerosol generating material by a resistance heating or induction heating method. However, recently, aerosol generating devices using a dielectric heating method to heat an aerosol generating material by using microwaves have been introduced.

An aerosol generating device using a dielectric heating method generates heat in a dielectric included in an aerosol generating material through microwave resonance and heats the aerosol generating material through the heat generated in the dielectric.

To increase use convenience of the aerosol generating device using the dielectric heating method, a heater assembly for generating microwave resonance is required to be miniaturized. However, when a heater assembly is miniaturized, although use convenience is increased, the dielectric heating efficiency may deteriorate. Therefore, there is a growing need for an aerosol generating device using a dielectric heating method and including a heater assembly having a new structure that may increase the dielectric heating efficiency while allowing miniaturization of the heater assembly.

### SUMMARY

Provided is an aerosol generating device capable of blocking leakage of microwaves or electromagnetic waves to the outside when detachment of an aerosol generating article is detected.

Problems to be solved through embodiments of the disclosure are not limited to the above-described problems, and problems not mentioned may be clearly understood by one of ordinary skill in the art to which the embodiments belong from the description and accompanying drawings.

Additional aspects will be set forth in part in the description which follows and, in part, will be apparent from the description, or may be learned by practice of the presented embodiments of the disclosure.

An aerosol generating device according to an embodiment may include a source unit configured to generate microwaves, a resonating unit including an accommodation space for accommodating an aerosol generating article and configured to generate microwave resonance due to the microwaves generated by the source unit, a cover arranged in the resonating unit to move between an opening position to open the accommodation space and a closing position to close the accommodation space, and a control unit configured to control the source unit based on an external force applied by the aerosol generating article to the cover.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an aerosol generating device according to an embodiment;

FIG. 2 is a perspective view of an aerosol generating device according to an embodiment;

FIG. 3 is a perspective view of a heater assembly according to an embodiment;

FIG. 4 is a cross-sectional view of the heater assembly taken along line IV-IV of FIG. 3;

FIG. 5A is a side view illustrating a shape of an aerosol generating article before the aerosol generating article is inserted into an aerosol generating device including a cover, according to an embodiment;

FIG. 5B is a side view illustrating a shape of an aerosol generating article completely inserted into an aerosol generating device including a cover, according to an embodiment;

FIG. 5C is a side view illustrating a shape of an aerosol generating article detached from an aerosol generating device including a cover, according to an embodiment;

FIG. 6 is a side view illustrating another shape of an aerosol generating article detached from an aerosol generating device including a cover, according to an embodiment;

FIG. 7A illustrates a connecting circuit in a closed-circuit state, according to an embodiment;

FIG. 7B illustrates a connecting circuit in an open-circuit state, according to an embodiment;

FIG. 8A illustrates a connecting circuit in a closed-circuit state, according to another embodiment;

FIG. 8B illustrates a connecting circuit in an open-circuit state, according to another embodiment;

FIG. 9A is a side view illustrating a shape of an aerosol generating article before the aerosol generating article is inserted into an aerosol generating device including a cover, according to another embodiment; and

FIG. 9B is a side view illustrating a shape of an aerosol generating article completely inserted into an aerosol generating device including a cover, according to another embodiment.

### DETAILED DESCRIPTION

Hereinafter, embodiments will be described in detail with reference to the accompanying drawings, and the same or similar components will be assigned the same reference numerals regardless of the reference numerals in the drawings, and the same descriptions thereof will be omitted. With regard to the description of the drawings, like reference numerals may be used to represent like or related elements.

The suffixes “module”, “unit”, “-er”, and “-or” for the components used in the following description are given or used interchangeably by considering only the ease of writing the description, and do not have distinct meanings or roles in themselves. The suffix “module” or “unit”, as used herein, may include a unit implemented as hardware, software, or firmware. For example, the suffix “module” or “unit” may be interchangeably used with the term a “logic”, a “logical block”, a “component”, or a “circuit”. The “module” or “unit” may be an integrally formed component, a minimum unit of the component performing one or more functions, or a part of the minimum unit. For example, the “module” or “unit” may be implemented in the form of an application-specific integrated circuit (ASIC).

In addition, when describing the embodiments of the disclosure, the detailed description of the related known art, which may obscure the subject matter of the embodiments, may be omitted. Also, the accompanying drawings are only intended to facilitate understanding of the embodiments described herein, and the spirit of the disclosure is not limited by the accompanying drawings and should be understood to include all changes, equivalents or alternatives included in the spirit and scope of the disclosure.

Although the terms first, second, etc. may be used herein to describe various elements or components, these elements or components should not be limited by these terms. These terms are only used to distinguish one element or component from another element or component.

When an element is referred to as being “connected to” or “coupled to” another element, it may be directly connected or coupled to the other element or intervening elements may be present. In contrast, when an element is referred to as being “directly connected to” or “directly coupled to” another element, there are no intervening elements present.

The singular forms are intended to include the plural forms as well, unless the context clearly indicates otherwise.

Various embodiments of the present disclosure may be implemented as software including one or more instructions stored in a storage medium (e.g., a memory) readable by a machine (e.g., an aerosol generating device 1). For example, a processor (e.g., the processor 170) of the machine (e.g., the aerosol generating device 1) may call at least one instruction among one or more instructions stored from the storage medium and execute the at least one instruction. This makes it possible for the machine to be operated to perform at least one function according to the called at least one instruction. Examples of the one or more instructions may include codes created by a compiler, or codes executable by an interpreter. A machine-readable storage medium may be provided as a non-transitory storage medium. The ‘non-transitory storage medium’ is a tangible device and only means that it does not contain a signal (e.g., electromagnetic waves). This term does not distinguish a case in which data is stored semi-permanently in a storage medium from a case in which data is temporarily stored.

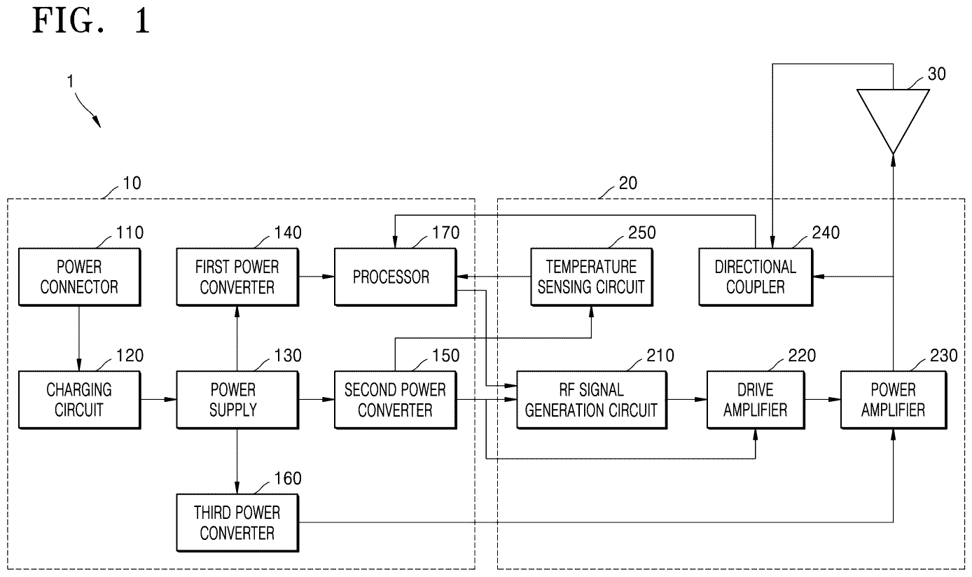

FIG. 1 is a block diagram of an aerosol generating device 1 according to an embodiment.

According to an embodiment, the aerosol generating device 1 may include a control unit 10, a source unit 20, and a radiating unit 30. The control unit 10 may refer to a circuit for controlling the basic operation of the aerosol generating device 1. The source unit 20 may refer to a circuit for generating a radio frequency (RF) signal under the control by the control unit 10. The radiating unit 30 may be a device for radiating an RF signal generated by the source unit 20 in the form of electromagnetic waves into a space into which an aerosol-generating article is inserted (hereinafter, “insertion space”). Charges or ions of a dielectric (e.g., glycerin) included in an aerosol-generating article may vibrate or rotate due to radiated electromagnetic waves (e.g., RF signals), and the aerosol-generating article may be heated as the dielectric generates heat due to frictional heat generated in the process of the charges or ions vibrating or rotating. In other words, the aerosol generating device 1 may be a device that generates an aerosol by heating an aerosol-generating article in a dielectric heating manner.

In an embodiment, the control unit 10 may include a power connector 110, a charging circuit 120, a power supply 130, a first power converter 140, a second power converter 150, a third power converter 160, and/or a processor 170. Additionally, the source unit 20 may include an RF signal generation circuit 210, a drive amplifier 220, a power amplifier 230, a directional coupler 240, and/or a temperature sensing circuit 250. However, it will be understood by those skilled in the art related to the present embodiment that some of the components illustrated in FIG. 1 may be omitted or new components may be added according to the design of the aerosol generating device 1.

The power connector 110 may refer to a physical connection device that is electrically connected to an electronic device or system (e.g., an external power supply) outside the aerosol generating device 1 and used to transmit and receive power. For example, the power connector 110 may receive power from an external power supply and transmit the received power to a component requiring charging (e.g., the power supply 130). The power connector 110 may also provide a path for data transmission. In this case, the power connector 110 may be referred to as a data and power connector. The aerosol generating device 1 may transmit and receive data to or from an external electronic device or system (e.g., a smartphone, a computer, etc.) through the power connector 110. The power connector 110 may include a Universal Serial Bus (USB) power connector, a direct current (DC) power connector, etc. In an example, the power connector 110 may include, but is not limited to, a USB-C type connector capable of supplying 9 V of direct current (DC) voltage at a current of 1 A. The power connector 110 may also include an interface for transmitting and receiving power wirelessly.

The charging circuit 120 may refer to a circuit for charging the power supply 130. The charging circuit 120 may charge the power supply 130 by using power transmitted from the power connector 110. In an example, the charging circuit 120 may be implemented as a charger IC, which is an integrated circuit (IC) that performs functions for efficiently and safely charging the power supply 130. The charging circuit 120 may monitor the charging status of the power supply 130 or optimize the charging process by monitoring the voltage, current, and/or temperature of the power supply 130. For example, the charging circuit 120 may detect the status of the power supply 130 and prevent overcharging or overdischarging by providing an appropriate charging voltage and current.

The power supply 130 may supply power for the operation of the aerosol generating device 1. The power supply 130 may include one or more rechargeable batteries. The power supply 130 may supply power to the radiating unit 30 such that the radiating unit 30 may radiate electromagnetic waves (e.g., RF signals) into the insertion space to heat an aerosol-generating article. Here, power supply to the radiating unit 30 may indicate power supply to the source unit 20. Additionally, the power supply 130 may supply power required for the operation of the processor 170, the RF signal generation circuit 210, the drive amplifier 220, the power amplifier 230, the temperature sensing circuit 250, etc. In an example, the power supply 130 may include, but is not limited to, a lithium polymer (LiPoly) battery. The power supply 130 may be a replaceable type (separated type) battery (hereinafter, a removable battery). The removable battery may be mounted in a battery holder provided within the aerosol generating device 1 or removed from the battery holder. The removable battery may be charged in a wired manner and/or wirelessly.

The aerosol generating device 1 may include a power conversion circuit for converting power supplied from the power supply 130 into power (e.g., voltage and/or current) suitable for other components. The power conversion circuit may include at least one of a buck converter, a buck-boost converter, a boost converter, a Zener diode, and a low-dropout (LDO) regulator. Additionally, the power conversion circuit may include a DC/AC converter (e.g., an inverter) as required.

In an example, the aerosol generating device 1 may include the first power converter 140, the second power converter 150, and the third power converter 160. The first power converter 140 may be an LDO regulator for supplying power (e.g., a DC of 3.3 V) suitable for the processor 170, the second power converter 150 may be a buck-boost converter for supplying power (e.g., a DC of 5 V) suitable for the temperature sensing circuit 250, the RF signal generation circuit 210, and the drive amplifier 220, and the third power converter 160 may be a boost converter for supplying power (e.g., a DC of 12 V/25 W) suitable for the power amplifier 230.

However, the first power converter 140, the second power converter 150, and the third power converter 160 are not limited to the examples described above and may include other types of power conversion circuits. Additionally, although FIG. 1 illustrates the aerosol generating device 1 including three power converters, the aerosol generating device 1 may include more than three power converters or may include fewer power converters. In an example, at least some of the first power converter 140, the second power converter 150, and the third power converter 160 may be integrated into a single power converter.

The processor 170 may control the overall operation of the aerosol generating device 1. For example, the processor 170 may directly or indirectly control charging and discharging of the power supply 130 by using the charging circuit 120. Additionally, the processor 170 may control the voltage and/or current output by a power conversion circuit by controlling the frequency and/or duty ratio of a current pulse input to at least one switching element of the power conversion circuit. In addition to the components described above, the processor 170 may also control the overall operation of other components to be described later.

The processor 170 may be implemented as an array of multiple logic gates, or may be implemented as a combination of a general-purpose microcontroller unit (MCU) (or microprocessor) and a memory storing a program that may be executed in the MCU. Additionally, it will be understood by those skilled in the art that the processor 170 may be implemented in other forms of hardware.

The RF signal generation circuit 210 may generate an RF signal based on power delivered from the power supply 130 or the second power converter 150. An RF signal may refer to a signal having a frequency within a range of about 300 MHz to about 300 GHz. In an example, the RF signal may have a frequency of about 1 GHz to about 100 GHz. Additionally, the RF signal may have a frequency in the Industrial Scientific and Medical equipment (ISM) band, for example, 915 MHz, 2.45 GHz, and/or 5.8 GHz.

The RF signal generation circuit 210 may include a voltage-controlled oscillator (VCO) that generates an RF signal having a different frequency depending on an input voltage. The RF signal generation circuit 210 may receive a control signal (e.g., a DC signal) from the processor 170 and generate an RF signal having a frequency corresponding to the received control signal. The processor 170 may store a control signal corresponding to a desired frequency in the form of a look-up table, or calculate a control signal corresponding to a desired frequency in real time through at least one operation.

In an example, the aerosol generating device 1 may further include a digital to analog converter (D/A converter) for converting a digital control signal output from the processor 170 into an analog control signal. The RF signal generation circuit 210 may receive the analog control signal and generate an RF signal having a frequency corresponding to the received analog control signal.

The drive amplifier 220 may amplify the RF signal generated by the RF signal generation circuit 210. For example, the drive amplifier 220 may provide an input signal suitable for a component of a next stage (e.g., the power amplifier 230) by amplifying the signal level (e.g., amplitude) of the RF signal. The drive amplifier 220 may minimize signal distortion by maintaining high linearity. However, since the drive amplifier 220 is an amplifier focused on increasing the signal level, the drive amplifier 220 may provide relatively low output power.

The power amplifier 230 may amplify power of an RF signal received from the drive amplifier 220. The power amplifier 230 may be an amplifier focused on providing sufficient power to a final output device (e.g., the radiating unit 30). For example, the power amplifier 230 may provide a high-power RF signal to the radiating unit 30 so that the radiating unit 30 may radiate electromagnetic waves into the insertion space to heat an aerosol-generating article. The power amplifier 230 may perform an amplification operation by using power received through the third power converter 160 that provides higher power and/or voltage than the second power converter 150.

The drive amplifier 220 and the power amplifier 230 may include transistors such as a bipolar junction transistor (BJT), a field effect transistor (FET), or a vacuum tube. In an example, the drive amplifier 220 and the power amplifier 230 may be, but are not limited to, gallium nitride (GaN) transistors configured to handle high efficiency, high speed, and high voltage. The drive amplifier 220 and the power amplifier 230 may also include an operational amplifier.

In FIG. 1, the drive amplifier 220 and the power amplifier 230 are illustrated as individual amplifiers, but the drive amplifier 220 and the power amplifier 230 may be integrated into a single amplifier. Additionally, the drive amplifier 220 and/or the power amplifier 230 may be configured as a series connection, a parallel connection, and/or a combination thereof of a plurality of amplifiers.

The radiating unit 30 may include at least one antenna for radiating electromagnetic waves into space. At least one antenna may have a size and shape suitable for the size and shape of an aerosol-generating article. For example, if the aerosol-generating article is cylindrical in shape, at least one antenna may be tubular surrounding the aerosol-generating article that is cylindrical. Here, the shape of the antenna being tubular may indicate that the overall shape of the antenna is tubular. In other words, if the antenna is formed of a metal (e.g. SUS) track, this may indicate that the overall shape of the entire track is tubular. The shape of at least one antenna is not limited to the examples described above and may include various shapes such as a flat plate shape, a curved plate shape, etc.

The radiating unit 30 may heat the aerosol-generating article by radiating electromagnetic waves (e.g., an amplified RF signal or a transmitted RF signal) into the insertion space. For the heating efficiency of the aerosol generating article to be maximized, resonance of electromagnetic waves is to occur within the insertion space. The resonance conditions (e.g., resonant frequency) of the insertion space may vary depending on the amount of dielectric contained in the inserted aerosol-generating article. The processor 170 may control the frequency of an RF signal generated by the RF signal generation circuit 210 to correspond to or be close to the resonance condition of the insertion space by adjusting a control signal input to the RF signal generation circuit 210. The processor 170 may use the directional coupler 240 to obtain information about the resonance conditions of the insertion space.

The directional coupler 240 may refer to a passive element having a waveguide structure that separates an incident wave and a reflected wave from each other. The directional coupler 240 may receive an RF signal transmitted from the power amplifier 230 toward the radiating unit 30 and electromagnetic waves reflected from the insertion space after they are radiated by the radiating unit 30. The directional coupler 240 may separate the transmitted RF signal and the reflected electromagnetic waves, and provide them to the processor 170.

In an example, the aerosol generating device 1 may further include an analog to digital converter (A/D converter) for converting an analog output of the directional coupler 240 into a digital output. The A/D converter may be built into the processor 170 or may exist as a separate component outside the processor 170. The processor 170 may analyze the characteristics (e.g., current, voltage, power, phase, and/or frequency) of the transmitted RF signal and the characteristics (e.g., current, voltage, power, phase, and/or frequency) of the reflected electromagnetic waves by monitoring the output of the directional coupler 240.

The processor 170 may determine whether the operation of the source unit 20 is being performed as intended, based on the characteristics of the transmitted RF signal. Additionally, the characteristics of the transmitted RF signal may be used to determine the heating efficiency of the source unit 20 or the radiating unit 30, together with the characteristics of the reflected electromagnetic wave. The processor 170 may control the source unit 20 such that the heating efficiency of the source unit 20 or the radiating unit 30 is maximized. For example, the processor 170 may adjust the frequency of an RF signal generated by the RF signal generation circuit 210 such that the power of the reflected electromagnetic waves is minimized. Minimizing the power of the reflected electromagnetic waves may indicate that the frequency of the RF signal is closer to the resonance conditions of the insertion space. The characteristics of the transmitted RF signal may provide a criterion for whether the power of the reflected electromagnetic waves is minimized.

Since resonance of electromagnetic waves may occur in the insertion space depending on the frequency of the RF signal, the insertion space may be referred to as a resonant section. At least a portion of the insertion space may be surrounded by at least one shielding member to prevent electromagnetic waves from leaking outside the aerosol generating device 1. In an embodiment, the insertion space may further include a physical structure to ensure that the resonance conditions are within a range controllable by the processor 170. The physical structure may include at least one conductor, and the resonance conditions of the insertion space may vary depending on the arrangement, thickness, and length of the conductor. Additionally, the physical structure may include a space for accommodating a dielectric having low electromagnetic absorption, separate from the dielectric contained in the aerosol-generating article. A dielectric with low electromagnetic absorption may change the resonant frequency of the entire resonant section without absorbing the energy that are to be transferred to the heated material. Accordingly, even if the resonant section is reduced in size, the resonance conditions may be determined within a range controllable by the processor 170.

The temperature sensing circuit 250 may be arranged in contact with or adjacent to components included in the source unit 20 to measure the temperature of the source unit 20. For example, the temperature sensing circuit 250 may be arranged in contact with or adjacent to at least one of the RF signal generation circuit 210, the drive amplifier 220, and the power amplifier 230. Heat may be generated due to limited efficiency in the process of generating and/or amplifying RF signals, and if excessive heat is generated, this heat may have a negative impact on components included in the source unit 20 or other components included in the aerosol generating device 1. The temperature measured by the temperature sensing circuit 250 may be used to prevent overheating of the source unit 20.

The processor 170 may receive the temperature (or a value corresponding to the temperature) measured from the temperature sensing circuit 250, and if it is determined that the source unit 20 is overheated, the processor 70 may stop the operation of the source unit 20. For example, the processor 170 may stop the operation of the source unit 20 by cutting off the power supply to the source unit 20 or transmitting a control signal. Hereinafter, the term ‘power supply’ to the source unit 20 is used to indicate controlling whether the source unit 20 operates.

The temperature sensing circuit 250 may include at least one temperature sensor among a thermocouple, a resistance temperature detector (RTD), a thermistor, a semiconductor temperature sensor, and an optical temperature sensor. In an example, the temperature sensing circuit 250 may be implemented as a chip-type sensor (e.g., a negative temperature coefficient (NTC) sensor) to minimize the area occupied, but is not limited thereto.

The aerosol generating device 1 may include other components in addition to the components illustrated in FIG. 1. For example, the aerosol generating device 1 may further include a sensor unit, an output unit, an input unit, a communication unit, and a memory. In addition, if the aerosol generating device 1 is a hybrid type device that uses both an aerosol-generating article and a cartridge, the aerosol generating device 1 may further include a cartridge heater. The cartridge heater may receive power from the power supply 130 to heat a medium and/or an aerosol-generating material within the cartridge.

According to an embodiment, the sensor unit may detect the status of the aerosol generating device 1 or the status around the aerosol generating device 1 and transmit the detected information to the processor 170. For example, the sensor unit may include a temperature sensor, a puff sensor, an insertion detection sensor, a reuse detection sensor, an overly moist detection sensor, a cigarette identification sensor, a cartridge detection sensor, a cap detection sensor, and/or a motion detection sensor. The sensor unit may further include various sensors, such as a liquid remaining amount sensor for detecting the remaining liquid amount of the cartridge, and an immersion sensor for detecting immersion of the aerosol generating device 1.

In an embodiment, the temperature sensor may detect the temperature of the insertion space or the aerosol-generating article. The temperature sensor may be positioned in contact with or adjacent to the insertion space or the aerosol-generating article to directly measure the temperature of the insertion space or the aerosol-generating article. Additionally, the temperature sensor may be positioned to be spaced apart from the insertion space or the aerosol-generating article to indirectly measure the temperature of the insertion space or the aerosol-generating article (e.g., in a non-contact manner). In an example, the temperature sensor may include an optical temperature sensor (e.g., an infrared temperature sensor).

In an embodiment, the temperature sensor may detect the temperature of the power supply 130. The temperature sensor may be arranged adjacent to the power supply 130. For example, the temperature sensor may be attached to one surface of the power supply 130 (e.g., a battery) and/or mounted on one surface of a printed circuit board. For example, the aerosol generating device 1 may include a protection circuit module (PCM), and the temperature sensor may be positioned adjacent to the power supply 130 together with the PCM.

According to an embodiment, the temperature sensor may be arranged inside the housing (not shown) of the aerosol generating device 1 to detect the temperature inside the housing (not shown).

In an embodiment, the puff sensor may detect a user's puff.

As an example, the puff sensor may include a pressure sensor. The pressure sensor may output a signal corresponding to the internal pressure of the aerosol generating device 1, and the processor 170 may detect a user's puff based on the signal corresponding to the internal pressure. The internal pressure of the aerosol generating device 1 may correspond to pressure of an airflow path on which gas flows. The puff sensor may be disposed to correspond to the airflow path, through which gas flows, in the aerosol generating device 1.

In another example, the puff sensor may include a temperature sensor. When a user puffs, a temporary temperature drop may occur in the airflow path, the insertion space, the aerosol generating article, etc. The processor 170 may detect the user's puff based on a signal corresponding to the temperature of an airflow path, etc. output from a temperature sensor.

In another example, the puff sensor may include both a pressure sensor and a temperature sensor. In this case, the temperature sensor may measure the temperature which is used to correct the internal pressure measured by the pressure sensor. For example, the puff sensor may correct a signal corresponding to internal pressure based on a temperature measured by the temperature sensor and output the corrected signal. In another example, the puff sensor may output a signal corresponding to a temperature measured by the temperature sensor and a signal corresponding to the internal pressure measured by the puff sensor. In this case, the processor 170 may receive the signals and correct the signal corresponding to the internal pressure, based on the signal corresponding to the temperature.

In another example, the puff sensor may include a capacitance-based sensor. In the disclosure, the capacitance-based sensor may also be referred to as a capacitive sensor. When a user puffs, temperature changes and/or aerosol flow may occur within the insertion space, thereby changing the permittivity within the insertion space. The processor 170 may detect the user's puff based on a signal corresponding to the permittivity inside the insertion space output from the capacitive sensor.

The puff sensor is not limited to the examples described above and may be implemented with various sensors to detect the user's puff.

In an embodiment, the insertion detection sensor may detect insertion and/or removal of an aerosol-generating article. The insertion detection sensor may be installed around the insertion space.

As an example, the insertion detection sensor may include a capacitive sensor. The capacitive sensor may include at least one conductor, wherein the at least one conductor may be positioned adjacent to the insertion space. When an aerosol generating article is inserted or removed within the insertion space, the permittivity around the conductor may change. The processor 170 may detect insertion and/or removal of an aerosol-generating article based on a signal corresponding to the permittivity inside the insertion space output from the capacitive sensor.

In another example, the insertion detection sensor may include an inductive sensor. The inductive sensor may include at least one coil, wherein the at least one coil may be positioned adjacent to the insertion space. When an aerosol-generating article (e.g., a wrapper for the aerosol-generating article) contains a conductor, a change in the magnetic field may occur around the current-carrying coil when the aerosol-generating article is inserted into or removed from the insertion space. The processor 170 may detect insertion and/or removal of an aerosol-generating article including a conductor based on characteristics of a current output from or detected by an inductive sensor (e.g., frequency of an alternating current, current value, voltage value, inductance value, impedance value, etc.). Alternatively, the aerosol-generating article (e.g., the medium portion of the aerosol-generating article) may include a susceptor (e.g., SUS). Even in this case, a change in the magnetic field around the coil may occur based on the insertion or removal of a susceptor or the like within the insertion space, and the processor 170 may also detect the insertion and/or removal of the aerosol-generating article based on the characteristics of the current of the inductive sensor.

The insertion detection sensor is not limited to the examples described above and may be implemented using various sensors (e.g., proximity sensors, etc.) for detecting insertion and/or removal of an aerosol-generating article. Additionally, the insertion detection sensor may include any combination of the examples described above. In an embodiment, the insertion detection sensor may include a switch or the like for detecting compression by an aerosol-generating article.

In an embodiment, the reuse detection sensor may detect whether an aerosol-generating article has been reused. As an example, the reuse detection sensor may be a color sensor for detecting the color of the aerosol generating article. When the aerosol-generating article is used by a user, a change in color of a portion of the wrapper surrounding the outside of the aerosol-generating article may occur due to the generated aerosol or heating. The color sensor may output a signal corresponding to optical characteristics (e.g., wavelength of light) corresponding to the color of the wrapper based on light reflected from the wrapper. The processor 170 may determine that the aerosol-generating article inserted into the insertion space has already been used if a change in color of a portion of the wrapper is detected.

In an embodiment, the overly moist detection sensor may detect whether the aerosol-generating article is overly moist. For example, the overly moist detection sensor may include a capacitive sensor. The capacitive sensor may include at least one conductor positioned adjacent to the insertion space. The processor 170 may detect whether the aerosol-generating article is overly moist, based on the level of a signal corresponding to a permittivity or the like output from the capacitive sensor. For example, the processor 170 may determine a level range within which the level of the signal is included, based on a look-up table, and determine the moisture content of the aerosol-generating article based on the determined level range.

In an embodiment, the cigarette identification sensor may detect whether the aerosol-generating article is authentic and/or detect the type of the aerosol-generating article.

As an example, the cigarette identification sensor may include an optical sensor for detecting an identification material (or identification tag) located on an outer surface of an aerosol-generating article (e.g., a wrapper). The optical sensor may irradiate light toward the identification material (or identification mark) of the aerosol-generating article and detect, based on the reflected light, the authenticity and/or type of the aerosol-generating article. For example, the identification material may include a material that emits light of a particular wavelength, based on the irradiated light. The processor 170 may detect whether the aerosol-generating article is authentic and/or the type of the article based on the range of the wavelength.

In another example, the cigarette identification sensor may include a capacitive sensor. Depending on the type of aerosol generating article inserted into the insertion space, the permittivity inside the insertion space may vary. The processor 170 may detect whether the aerosol generating article is authentic and/or the type thereof based on a signal corresponding to the permittivity inside the insertion space output from the capacitive sensor.

In another example, the cigarette identification sensor may include an inductive sensor. When a conductor is included in a wrapper and/or interior (e.g., medium portion) of an aerosol-generating article inserted into the insertion space, the characteristics of the current detected by the inductive sensor (e.g., frequency of AC current, current value, voltage value, inductance value, impedance value, etc.) may differ depending on the type of the aerosol-generating article inserted into the insertion space. The processor 170 may detect whether the inserted aerosol-generating article is authentic and/or the type thereof based on the characteristics of the current output from or detected by the inductive sensor.

The cigarette identification sensor is not limited to the examples described above and may be implemented using various sensors to detect whether the aerosol-generating article is authentic and/or to detect the type of the aerosol-generating article. Additionally, the cigarette identification sensor may include any combination of the examples described above.

In an embodiment, the cartridge detection sensor may detect mounting and/or removal of a cartridge. For example, the cartridge detection sensor may include an inductive sensor, a capacitive sensor, a resistive sensor, a hall sensor (hall IC) and/or an optical sensor.

In an embodiment, the cap detection sensor may detect attachment and/or removal of a cap. For example, the cap detection sensor may include an inductive sensor, a capacitive sensor, a resistive sensor, a contact sensor, a hall sensor (hall IC) and/or an optical sensor. The cap may include a structure that covers at least a portion of a cartridge mounted or inserted into the aerosol generating device 1, or covers at least a portion of the housing of the aerosol generating device 1. The cap detection sensor may output a signal corresponding to the mounting or removal of the cap when the cap is mounted on or removed from the housing, and the processor 170 may detect the mounting or removal of the cap based on the signal corresponding to the mounting or removal.

According to an embodiment, the motion detection sensor may detect movement of the aerosol generating device 1. The motion detection sensor may be implemented using at least one of an acceleration sensor or a gyro sensor.

According to an embodiment, the sensor unit may further include, in addition to the sensors described above, at least one of a humidity sensor, an atmospheric pressure sensor, a magnetic sensor, a position sensor (global positioning system (GPS)), or a proximity sensor. The functions of the sensors would be instinctively understood by one of ordinary skill in the art in view of their names and thus detailed descriptions thereof are omitted herein.

According to an embodiment, the output unit may output information about the status of the aerosol generating device 1. The output unit may include, but is not limited to, a display, a haptic unit, and/or an audio output unit. For example, information about the aerosol generating device 1 may include the charging/discharging status of the power supply 130 of the aerosol generating device 1, the operating status of the source unit 20 or the radiating unit 30, the insertion/removal status of the aerosol-generating article and/or cartridge, the mounting and/or removal status of the cap, or the status in which the use of the aerosol generating device 1 is limited (e.g., detection of an abnormal article). The display may visually provide information to the user about the status of the aerosol generating device 1. For example, the display may include a light-emitting diode (LED) light emitting element, a liquid crystal display (LCD) panel, an organic light-emitting diode (OLED) display panel, etc. The display, if the display includes a touchpad, may also be used as an input device. The haptic unit may provide tactile information to the user about the status of the aerosol generating device 1. For example, the haptic component may include a vibration motor, a piezoelectric element, an electrical stimulation device, and the like. The audio output unit may provide information about the aerosol generating device 1 to the user audibly. For example, the audio output unit may convert an electrical signal into an audio signal and output the same externally.

According to an embodiment, the input unit may receive information input from a user. For example, the input unit may include a touch panel, a button, a key pad, a dome switch, a jog wheel, a jog switch, and the like.

According to an embodiment, the memory may be hardware that stores various data processed within the aerosol generating device 1, and may store data processed by the processor 170 and data to be processed. For example, the memory may include at least one type of storage medium among a flash memory type, a hard disk type, a multimedia card micro type, a card type memory (e.g., an SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. For example, the memory may store data about the operation time of the aerosol generating device 1, the maximum number of puffs, the current number of puffs, at least one temperature profile, and the user's smoking pattern.

According to an embodiment, the communication unit may include at least one component for communicating with another electronic device (e.g., a portable electronic device). For example, the communication unit may include a Bluetooth communication unit, a Bluetooth Low Energy (BLE) communication unit, a near field Communication unit, a wireless local area network (WLAN) communication unit, a Zigbee communication unit, an infrared (Infrared Data Association (IrDA)) communication unit, a wireless fidelity direct (WFD) communication unit, a ultra-wideband (UWB) communication unit, an Adaptive Network Topology (ANT)+communication unit, a cellular network communication unit, an Internet communication unit, a computer network (e.g., LAN or WAN) communication unit, etc.

According to an embodiment, the processor 170 may control the temperature of the insertion space or the aerosol-generating article by controlling an amplification factor of the source unit 20 (e.g., the power amplifier 230). The processor 170 may control the amplification factor of the source unit 20 (e.g., the power amplifier 230) based on the temperature of the insertion space or the aerosol-generating article detected using the temperature sensor. The processor 170 may control the amplification factor of the source unit 20 (e.g., the power amplifier 230) based on the temperature profile and/or power profile stored in the memory.

Additionally, the processor 170 may control the temperature of the cartridge heater by controlling the supply of power from the power supply 130 to the cartridge heater. The processor 170 may control the temperature of the cartridge heater and/or power supplied to the cartridge heater, based on the temperature of the cartridge heater detected using the temperature sensor. The processor 170 may control the temperature of the cartridge heater and/or the power supplied to the cartridge heater based on the temperature profile and/or power profile stored in the memory.

In an embodiment, the processor 170 may prevent the insertion space, the aerosol-generating article, and/or the cartridge heater from overheating. For example, the processor 170 may control the operation of the power conversion circuit to reduce the amount of power supplied to the source unit 20 or the cartridge heater, or to stop supplying power to the source unit 20 or the cartridge heater, based on a determination that temperature of the insertion space, the aerosol-generating article, and/or the cartridge heater exceeds a preset threshold temperature.

According to an embodiment, the processor 170 may control power supply to the source unit 20 or the cartridge heater, based on a result detected by the sensor unit.

In an embodiment, the processor 170 may control power supply to the source unit 20 or the cartridge heater based on insertion and/or removal of the aerosol-generating article into the insertion space. For example, the processor 170 may control power to be supplied to the source unit 20 or the cartridge heater when it is determined that the aerosol-generating article has been inserted into the insertion space using the insertion detection sensor. The processor 170 may cut off the power supply to the source unit 20 or the cartridge heater if it is determined that the aerosol-generating article has been removed from the insertion space using the insertion detection sensor. The processor 170 may determine that the aerosol-generating article has been removed from the insertion space, if the temperature of the insertion space or the aerosol-generating article is above a limited temperature or if the temperature change gradient of the insertion space or the aerosol-generating article is equal to or above a set gradient.

In an embodiment, the processor 170 may control the power supply time and/or power supply amount of power supplied to the source unit 20 or the cartridge heater, based on the state of the aerosol-generating article. For example, the processor 170 may increase the power supply time (e.g., preheating time) of power supply to the source unit 20 or the cartridge heater, if it is determined that the aerosol-generating article is in an overly moist state by using the overly moist detection sensor.

In an embodiment, the processor 170 may control power supply to the source unit 20 or the cartridge heater based on whether the aerosol-generating article is to be reused. For example, the processor 170 may cut off power supply to the source unit 20 or the cartridge heater if it is determined that the aerosol-generating article has been used.

In an embodiment, the processor 170 may control power supply to the source unit 20 or the cartridge heater, based on whether the cartridge is engaged and/or removed. For example, the processor 170 may stop supplying power to the source unit 20 or the cartridge heater or control power not to be supplied to the source unit 20 or the cartridge heater if it is determined, by using the cartridge detection sensor, that the cartridge is removed.

In an embodiment, the processor 170 may control power supply to the source unit 20 or the cartridge heater based on whether the aerosol-generating material in the cartridge has been exhausted. For example, the processor 170 may determine that the aerosol-generating material in the cartridge is exhausted if it is determined that the temperature of the cartridge heater exceeds a limit temperature while preheating the cartridge heater (i.e., during the preheating period). If it is determined that the aerosol-generating material in the cartridge has been exhausted, the processor 170 may cut off the supply of power to the source unit 20 or the cartridge heater.

In an embodiment, the processor 170 may control power supply to the source unit 20 or the cartridge heater based on the availability of the cartridge. For example, the processor 170 may determine that the cartridge is no longer usable if it is determined that the current number of puffs is equal to or greater than the maximum number of puffs set for the cartridge based on data stored in the memory. Alternatively, the processor 170 may determine that the cartridge is unusable if the total time that the cartridge heater has been heated is equal to or greater than a preset maximum time or the total amount of power supplied to the cartridge heater is equal to or greater than a preset maximum amount of power. In this case, the processor 170 may stop supplying power to the source unit 20 or the cartridge heater or control power not to be supplied to the source unit 20 or the cartridge heater.

In an embodiment, the processor 170 may control power supply to the source unit 20 or the cartridge heater based on the user's puff. For example, the processor 170 may use a puff sensor to determine whether a puff has occurred and/or the intensity of the puff. The processor 170 may cut off the power supply to the source unit 20 or the cartridge heater if the number of puffs reaches a preset maximum number of puffs and/or if no puffs are detected for a preset period of time. The processor 170 may also control the supply of power to the source unit 20 or the cartridge heater when a puff is detected.

In an embodiment, the processor 170 may control power supply to the source unit 20 or the cartridge heater based on the authenticity and/or type of the aerosol-generating article (or the cartridge). For example, the processor 170 may use the cigarette identification sensor to detect the authenticity and/or type of the aerosol-generating article (or the cartridge). For example, the processor 170 may cut off power supply to the source unit 20 or the cartridge heater if the aerosol-generating article (or the cartridge) is detected to be counterfeit. The processor 170 may control (e.g., initiate) the supply of power to the source unit 20 or the cartridge heater when the aerosol-generating article (or the cartridge) is detected to be authentic. In another example, the processor 170 may control power supply to the source unit 20 or the cartridge heater differently depending on the type of the aerosol-generating article (or the cartridge). The processor 170 may control the amplification factor of the source unit 20 or the temperature and/or power of the cartridge heater, based on a first temperature profile (or a first power profile) when the aerosol-generating article (or the cartridge) is detected to be a first aerosol-generating article (or a first cartridge), and may control the amplification factor of the source unit 20 or the temperature and/or power of the cartridge heater, based on a second temperature profile (or a second power profile) when the aerosol-generating article (or the cartridge) is detected to be a second aerosol-generating article (or a second cartridge).

According to an embodiment, the processor 170 may control the output unit based on a result detected by the sensor unit. For example, the processor 170 may control the output unit to provide visual, tactile and/or auditory information indicating that the aerosol generating device 1 is about to be terminated, when the number of puffs counted using the puff sensor reaches a preset number. For example, the processor 170 may control the output unit to provide visual, tactile and/or auditory information about the temperature of the insertion space, the aerosol-generating article, or the cartridge heater.

According to an embodiment, the processor 170 may store and update a history of events that occurred in the memory based on the occurrence of a given event. For example, the event may include operations such as detection of insertion of an aerosol-generating article, initiation of heating of an aerosol-generating article, detection of a puff, termination of a puff, detection of overheating, detection of overvoltage application to a cartridge heater, termination of heating of an aerosol-generating article, turning on/off power of the aerosol generating device 1, initiation of charging of the power supply 130, detection of overcharge of the power supply 130, termination of charging of the power supply 130, etc., performed in the aerosol generating device 1. For example, the history of events may include the time an event occurred, log data corresponding to the event, etc. For example, if a given event is detection of insertion of an aerosol-generating article, log data corresponding to the event may include data about sensing values of an insertion detection sensor, etc. For example, if a given event is overheating detection of a cartridge heater, log data corresponding to the event may include data about a temperature of the cartridge heater, a voltage applied to the cartridge heater, a current flowing through the cartridge heater, etc.

According to an embodiment, the processor 170 may control the communication unit to form a communication link with an external device, such as a user's mobile terminal.

According to an embodiment, the processor 170 may release a restriction on the use of at least one function (e.g., a heating function) of the aerosol generating device 1 when data regarding authentication is received from an external device via a communications link. For example, data regarding authentication may include the user's date of birth, a unique number that identifies the user, whether the user has completed authentication, etc.

According to an embodiment, the processor 170 may transmit data about the status of the aerosol generating device 1 to an external device via a communication link (e.g., remaining capacity of the power supply 130, operating mode, etc.). The transmitted data may be output through a display of an external device, etc.

According to an embodiment, when a request for location search of the aerosol generating device 1 is received from an external device via a communication link, the processor 170 may control the output unit to perform an operation corresponding to the location search. For example, the processor 170 may control the haptic unit to generate vibration or control the display to output an object corresponding to the location search and search termination.

According to an embodiment, the processor 170 may perform a firmware update when firmware data is received from an external device via a communication link.

According to an embodiment, the processor 170 may transmit data on sensed values of at least one sensor unit to an external server (not shown) via a communication link, and receive and store a learning model generated by learning the sensed values through machine learning, such as deep learning, from the server. The processor 170 may perform operations such as determining a user's inhalation pattern and generating a temperature profile using a learning model received from a server.

Although not illustrated in FIG. 1, the aerosol generating device 1 may further include a power protection circuit. The power protection circuit may include at least one switching element and may cut off the current path to the power supply 130 in response to overcharge and/or overdischarge of the power supply 130.

An aerosol-generating article as described herein may include at least one aerosol-generating rod (e.g., a medium portion) and at least one filter rod. The radiating unit 30 may be arranged to correspond to at least one aerosol-generating rod, and may be designed differently depending on the arrangement order and/or position of the aerosol-generating rod and the filter rod. The aerosol-generating rod may include at least one of nicotine, an aerosol-generating material, and an additive. For example, the aerosol-generating material may include glycerin (e.g., vegetable glycerin (VG)) and/or propylene glycol (PG), and may also include various other materials. For example, the additive may include flavoring agents and/or organic acids, and may also include various other substances. For example, the aerosol-generating rod may include an aerosol-generating substrate (e.g., a sheet) impregnated with a liquid non-tobacco material (e.g., an aerosol-generating material and/or nicotine), and/or may include a solid tobacco material (e.g., leaf tobacco, reconstituted tobacco, etc.). The tobacco material may be included in the aerosol-generating rod in various forms, such as cut tobacco, granules, or powder. In an embodiment, the additive of the aerosol-generating rod may include a basic substance. Based on the basic material, the nicotine of the tobacco material included in the aerosol-generating rod may have an alkaline pH (e.g., pH 7.0 or higher). In this case, freebase nicotine may be released from the aerosol-generating rod even at low temperatures. According to an embodiment, the aerosol-generating rod may include two or more aerosol-generating rods, wherein the two or more aerosol-generating rods may each include tobacco material and/or non-tobacco material. Although not shown, at least one aerosol-generating rod and at least one filter rod may be individually and/or integrally wrapped by at least one wrapper. In the disclosure, the aerosol-generating article may be referred to as a stick.

The cartridge referred to in the disclosure may include an aerosol-generating material having any one of a liquid state, a solid state, a gaseous state, or a gel state therein. The aerosol-generating material may include a liquid composition. For example, the liquid composition may be a liquid including a tobacco-containing material including a volatile tobacco flavor component, or may be a liquid including a non-tobacco material. The cartridge may include a storage portion containing an aerosol-generating material and/or a liquid transfer means impregnated with (containing) the aerosol-generating material. For example, the liquid transfer medium may include a wick such as cotton fibers, ceramic fibers, glass fibers, porous ceramics, etc. The cartridge heater may be included in the cartridge in the form of a coil surrounding (or winding) the liquid transfer means or in a structure contacting one side of the liquid transfer means. Alternatively, the cartridge heater may be included in the aerosol generating device 1 that is separable from the cartridge.

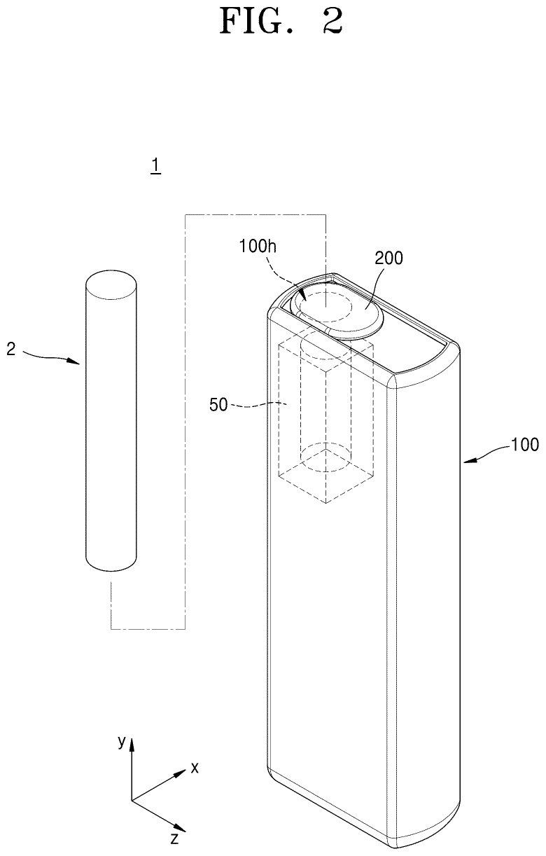

FIG. 2 is a perspective view of the aerosol generating device 1 according to an embodiment.

Referring to FIG. 2, the aerosol generating device 1 according to an embodiment may include a housing 100 for accommodating an aerosol generating article 2 and a heater assembly 50 for heating the aerosol generating article 2 accommodated in the housing 100.

The housing 100 may form the general exterior of the aerosol generating device 1, and components of the aerosol generating device 1 may be arranged in an inner space (or a “mounting space”) in the housing 100. For example, the heater assembly 50, and the control unit 10, the source unit 20, the radiating unit 30, and/or the sensor of FIG. 1 may be arranged in the inner space of the housing 100. However, the components arranged in the inner space are not limited thereto.

An insertion hole 100h may be formed in a portion of the housing 100, and at least a portion of the aerosol generating article 2 may be inserted into the housing 100 through the insertion hole 100h. For example, the insertion hole 100h may be formed in a portion of an upper end surface (e.g., a surface in a +y direction) of the housing 100, but a region in which the insertion hole 100h is formed is not limited thereto. According to another embodiment, the insertion hole 100h may be formed in a portion of a side surface (e.g., a surface in a +x direction) of the housing 100.

The heater assembly 50 may be arranged in the inner space of the housing 100 and may heat the aerosol generating article 2 inserted into or accommodated in the housing 100 through the insertion hole 100h. For example, the heater assembly 50 may be arranged to surround at least a portion of the aerosol generating article 2 inserted into or accommodated in the housing 100 and may heat the aerosol generating article 2.

According to an embodiment, the heater assembly 50 may heat the aerosol generating article 2 by using the dielectric heating method described with reference to FIG. 1. In the disclosure, a “dielectric heating method” may denote a method of heating a dielectric material, which is an object of heating, by using resonance of microwaves and/or an electric field (or a magnetic field) of microwaves. The microwaves may be an energy source for heating the object of heating and may be the same or substantially the same as the RF signal described with reference to FIG. 1. Microwaves may be generated by high-frequency power, and thus, this term may be interchangeably used with microwave power hereinafter.

Charges or ions of a dielectric material included in the aerosol generating article 2 may vibrate or rotate due to microwave resonance in the heater assembly 50, and through frictional heat generated in the process in which the charges or ions vibrate or rotate, heat may be generated in the dielectric material, so that the aerosol generating article 2 may be heated.

When the aerosol generating article 2 is heated by the heater assembly 50, aerosols may be generated from the aerosol generating article 2. In the disclosure, “aerosols” may denote gas particles generated by a mixture of vapor that is generated when the aerosol generating article 2 is heated with air.

The aerosols generated from the aerosol generating article 2 may pass through the aerosol generating article 2 or may be discharged to the outside of the aerosol generating device 1 through an empty space between the aerosol generating article 2 and the insertion hole 100h. A user may smoke by having his or her mouth in contact with a portion of the aerosol generating article 2 exposed to the outside of the housing 100 and inhaling aerosols discharged to the outside of the aerosol generating device 1.

The heater assembly 50 may include the source unit 20 and the radiating unit 30 of FIG. 1. The heater assembly 50 may heat the aerosol generating article 2 by receiving power from the power supply 130 (see FIG. 1).

Although not shown, the aerosol generating device 1 may further include a power conversion unit for converting direct current power received from the power supply 130 (see FIG. 1) into alternating current power. The power conversion unit may provide the converted alternating current power to the heater assembly 50. The power conversion unit may include an inverter including at least one switching device, and the processor 170 (see FIG. 1) may control on/off of the switching device included in the power conversion unit to convert direct current power into alternating current power. The power conversion unit may be formed as a full-bridge or a half-bridge. The power conversion unit may include at least one of the first power converter 140, the second power converter 150, or the third power converter 160 of FIG. 1.

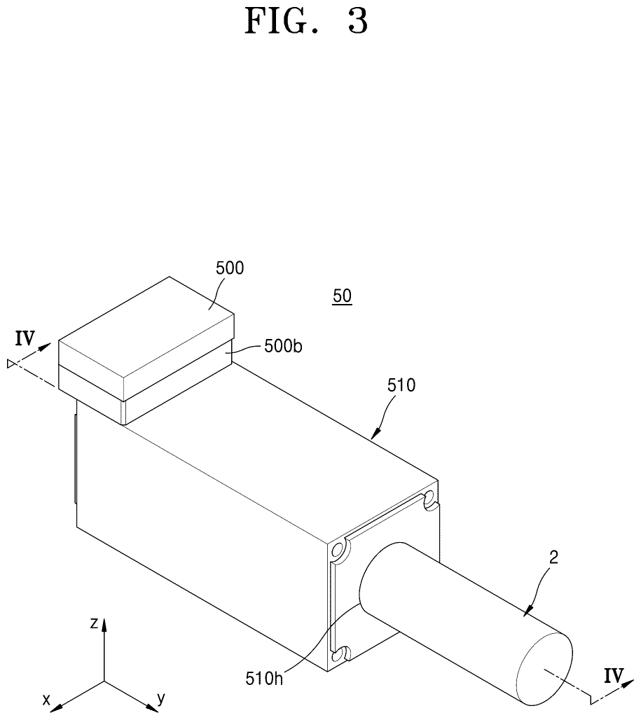

The heater assembly 50 may heat the aerosol generating article 2 by using microwaves and/or electric fields of microwaves (hereinafter, referred to as microwaves or microwave power, when distinction is not necessary). A heating method of the heater assembly 50 may correspond to a method of heating an object of heating by forming microwaves in a resonance structure, rather than by radiating microwaves by using an antenna. An example of the resonance structure will be described below with reference to FIG. 3 and thereafter.

The aerosol generating device 1 according to an embodiment may further include a cover 200 movably arranged on the housing 100 and configured to open or close the insertion hole 100h. For example, the cover 200 may expose the insertion hole 100h and an accommodation space to the outside of the aerosol generating device 1 or may cover the insertion hole 100h and the accommodation space so as not to expose the insertion hole 100h and the accommodation space to the outside of the aerosol generating device 1.

For example, the cover 200 may expose the insertion hole 100h and the accommodation space to the outside of the aerosol generating device 1 at an opening position. Here, the aerosol generating article 2 may be inserted into the housing 100 through the insertion hole 100h.

As another example, the cover 200 may cover the insertion hole 100h at a closing position not to expose the insertion hole 100h and the accommodation space to the outside of the aerosol generating device 1. When the aerosol generating device 1 is not in use, the cover 200 may prevent the introduction of external impurities into the heater assembly 50 through the insertion hole 100h.

FIG. 2 illustrates only the aerosol generating device 1 for heating the aerosol generating article 2 in a solid state, but the aerosol generating device 1 is not limited to the illustrated embodiment.

An aerosol generating device according to another embodiment may generate aerosols by heating, through the heater assembly 50, an aerosol generating material in a liquid or gel state (described with reference to FIG. 1), rather than the aerosol generating article 2 in the solid state.

An aerosol generating device according to another embodiment may include the heater assembly 50 for heating the aerosol generating article 2 and an aerosol generating material in a liquid or gel state and may further include a cartridge (or a “vaporizer”) for heating the aerosol generating material. Aerosols generated from the aerosol generating material may move to the aerosol generating article 2 through an air current path connected through the cartridge and the aerosol generating article 2, may be mixed with aerosols generated from the aerosol generating article 2, and then, may pass through the aerosol generating article 2 to be delivered to a user.

FIG. 3 is a perspective view of the heater assembly 50 according to an embodiment.

Referring to FIG. 3, the heater assembly 50 according to an embodiment may include a source unit 500 and a resonating unit 510. FIG. 3 may illustrate an embodiment of the heater assembly 50 described above. Hereinafter, redundant descriptions are omitted.

The heater assembly 50 may output microwaves, which have high frequencies, to the resonating unit 510. The microwaves may be power in an industrial scientific and medical equipment (ISM) band permitted for heating but are not limited thereto. The resonating unit 510 may be configured by taking into account a wavelength of the microwaves such that the microwaves may resonate in the resonating unit 510.

The aerosol generating article 2 may be inserted into the resonating unit 510, and a dielectric material in the aerosol generating article 2 may be heated by the resonating unit 510. For example, the aerosol generating article 2 may include a polar material, and molecules in the polar material may be polarized in the resonating unit 510. The molecules may vibrate or rotate due to a polarization phenomenon, and the aerosol generating article 2 may be heated by frictional heat, etc. generated in this process.

The source unit 500 may generate microwaves in a predetermined frequency band when power is supplied thereto. In the disclosure, the source unit 500 with reference to FIG. 3 and thereafter may be the same or substantially the same as the source unit 20 of FIG. 1.

The source unit 500 may generate high-frequency microwave power by receiving alternating current power from a power conversion unit. The microwave power may be selected from 915 MHz, 2.45 GHz, and 5.8 GHz frequency bands included in the ISM bands, but is not limited thereto.

The source unit 500 may include a solid-state based-RF-generating device, and based on the solid-state based-RF-generating device, may generate the microwave power. The solid-state based-RF-generating device may be realized as a semiconductor. When the source unit 500 is realized as a semiconductor, the heater assembly 50 may be miniaturized and may have the increased lifespan.

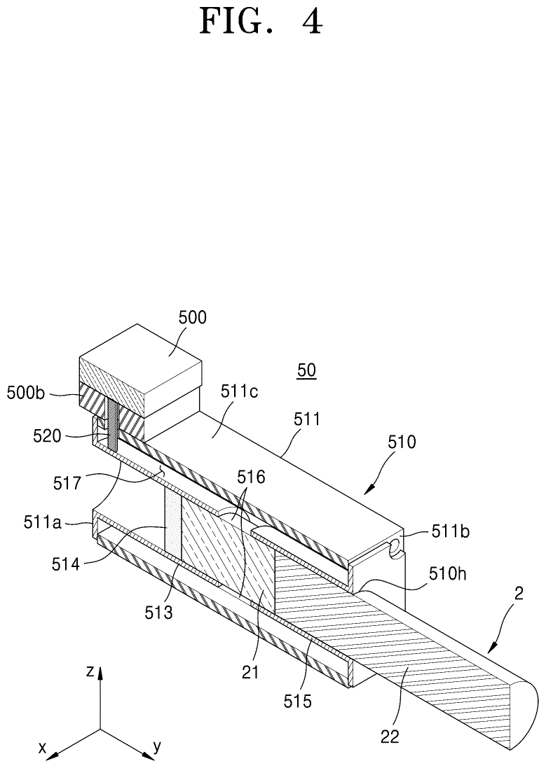

The source unit 500 may output the microwave power toward the resonating unit 510. In detail, the microwave power generated by the source unit 500 may be transmitted to the resonating unit 510 through a coupler 520 (see FIG. 4). The source unit 500 may include the power amplifier 230 (see FIG. 1) configured to increase or decrease microwave power, and the power amplifier 230 may adjust a size of the microwave power according to control by the processor 170 (see FIG. 1). For example, the power amplifier 230 may decrease or increase an amplitude of the microwaves. As the amplitude of the microwaves is adjusted, the microwave power may be adjusted.

The processor may adjust a size of the microwave power output by the source unit 500, based on a pre-stored temperature profile. For example, the temperature profile may include target temperature information according to a preheating section and a smoking section, and the source unit 500 may supply the microwave power as first power in the preheating section and supply the microwave power as second power which is less than the first power in the smoking section.

Although not shown, the aerosol generating device may further include a partitioning unit.

The partitioning unit may block the microwave power supplied from the resonating unit 510 toward the source unit 500. Most of the microwave power output by the source unit 500 may be absorbed by an object of heating, but according to a heated shape of the object of heating, some of the microwave power may be reflected by the object of heating and transferred again in a direction toward the source unit 500. That is because impedance in a direction from the source unit 500 toward the resonating unit 510 changes due to exhaustion of polar molecules according to heating of the object of heating. That “the impedance in the direction from the source unit 500 toward the resonating unit 510 changes” may denote the same as that “a resonating frequency of the resonating unit 510 changes.” When the microwave power reflected from the resonating unit 510 is input to the source unit 500, the source unit 500 may break down or may not perform expected output performance. The partitioning unit may not return the microwave power reflected by the resonating unit 510 to the source unit 500, but may guide the microwave power in a predetermined direction and absorb the microwave power. To this end, the partitioning unit may include a circulator and a dummy load.

According to an embodiment, the source unit 500 may be fixed to the resonating unit 510 so as not to be detached from the resonating unit 510 in a process of using the aerosol generating device. For example, the source unit 500 may be supported by a bracket 500b protruding in a +z direction in a portion of the resonating unit 510, thereby being fixed on the resonating unit 510. As another example, the source unit 500 may be attached on a portion of the resonating unit 510 without the bracket 500b, thereby being fixed on the resonating unit 510.

FIG. 3 illustrates only an embodiment in which the source unit 500 is fixed on a portion of the resonating unit 510 in a +z direction. However, a position of the source unit 500 is not limited to the illustrated embodiment. According to another embodiment, the source unit 500 may be fixed on another portion of the resonating unit 510 in a +x direction.

The resonating unit 510 may include an accommodation space 510h for accommodating at least a portion of the aerosol generating article 2 and may resonate the microwaves generated by the source unit 500 to heat the aerosol generating article 2 through a dielectric heating method. For example, through microwave resonance, charges of glycerin included in the aerosol generating article 2 may vibrate or rotate, and through frictional heat generated during vibration or rotation of the charges, heat may be generated in the glycerin, so that the aerosol generating article 2 may be heated.

According to an embodiment, the resonating unit 510 may include a material having a low microwave absorption rate to prevent its absorption of microwaves generated by the source unit 500.

FIG. 4 is a cross-sectional view of the heater assembly 50 taken along line IV-IV of FIG. 3.

Referring to FIG. 4, the heater assembly 50 according to an embodiment may include the source unit 500, the resonating unit 510, and the coupler 520. At least one (for example, the source unit 500) of the components of the heater assembly 50 illustrated in FIG. 4 is described above, and redundant descriptions are omitted hereinafter.

The resonating unit 510 may heat an object of heating by forming microwaves in a resonance structure. The resonating unit 510 may include the accommodation space 510h for accommodating the aerosol generating article 2, and the aerosol generating article 2 may be dielectrically heated through exposure to the microwaves.

The resonating unit 510 may include at least one inner conductor for resonating microwaves, and according to an arrangement, thickness, length, etc. of the inner conductor, the microwaves may resonate in the resonating unit 510.

The resonating unit 510 may be configured by taking into account a wavelength of microwaves such that the microwaves may resonate in the resonating unit 510. In order that the microwaves may resonate in the resonating unit 510, a short end having a closed cross-section and an open end in the opposite direction to the short end and having a cross-section having at least an open portion are required. Also, a length between the short end and the open end has to be set as an integer multiple of ¼ of the wavelength of the microwaves. For device miniaturization, the resonating unit 510 according to the disclosure may select the length of ¼ of the wavelength of the microwaves. In other words, the length between the short end and the open end of the resonating unit 510 may be set to be ¼ of the wavelength of the microwaves.

The coupler 520 may perform a function of inputting microwave power to the resonating unit 510. The coupler 520 may be realized as a subminiature version A (SMA), subminiature version B (SMB), micro coaxial (MCX), or micro miniature coaxial (MMCX) connector. The coupler 520 may connect a microwaves source in the form of a chip to the resonating unit 510, and thus, may transmit the microwave power generated by the source unit 500 to the resonating unit 510. In the disclosure, the coupler 520 may also be referred to by the term “microwave output unit.”

According to an embodiment, the aerosol generating article 2 may include an aerosol generating rod 21 and a filter rod 22. The aerosol generating rod 21 and the filter rod 22 are described above with reference to FIG. 1, and thus, redundant descriptions are omitted.

According to an embodiment, the resonating unit 510 may include an outer conductor 511, a first inner conductor 513, and a second inner conductor 515.

The outer conductor 511 may form the general exterior of the resonating unit 510 and may have an inner portion having an empty hollow shape, so that the components of the resonating unit 510 may be arranged in the outer conductor 511. The outer conductor 511 may include the accommodation space 510h for accommodating the aerosol generating article 2, and the aerosol generating article 2 may be inserted into the outer conductor 511 through the accommodation space 510h.

According to an embodiment, the outer conductor 511 may include a first surface 511a, a second surface 511b arranged to face the first surface 511a, and a side surface 511c surrounding an empty space between the first surface 511a and the second surface 511b. At least some (e.g., the first inner conductor 513 and the second inner conductor 515) of the components of the resonating unit 510 may be arranged in an inner space of the resonating unit 510 formed by the first surface 511a, the second surface 511b, and the side surface 511c.

The first inner conductor 513 may be formed to have a hollow cylindrical shape extending in a direction from the first surface 511a of the outer conductor 511 toward an inner space of the outer conductor 511.

According to an embodiment, a portion of the first inner conductor 513 may be in contact with the coupler 520 connected to the source unit 500, and microwaves generated by the source unit 500 may be transmitted to the first inner conductor 513 through the coupler 520. For example, the coupler 520 may be arranged to pass through the outer conductor 511 and have an end in contact with the source unit 500 and another end in contact with a portion of the first inner conductor 513, and the microwaves generated by the source unit 500 may be transmitted to the first inner conductor 513 through the coupler 520.

Here, the coupler 520 may be arranged to pass through the outer conductor 511 without being in contact with the outer conductor 511, for the transmission of microwaves. However, when the microwaves generated by the source unit 500 may be transmitted to the first inner conductor 513, the arrangement structure of the coupler 520 is not limited thereto.

A first region formed between the outer conductor 511 and the first inner conductor 513 may operate as a “first resonator” configured to generate an electric field through microwave resonance. The first region may indicate a space formed by the first surface 511a and the side surface 511c of the outer conductor 511 and the first inner conductor 513, and the microwaves transmitted through the coupler 520 may resonate in the first region to generate an electric field.

The second inner conductor 515 may be formed to have a hollow cylindrical shape extending in a direction from the second surface 511b of the outer conductor 511 toward the inner space of the outer conductor 511. The second inner conductor 515 may be arranged to be apart from the first inner conductor 513 by a predetermined distance in the inner space of the outer conductor 511, and a gap 516 may be formed between the first inner conductor 513 and the second inner conductor 515.

A second region formed between the outer conductor 511 and the second inner conductor 515 may operate as a “second resonator” configured to generate an electric field through microwave resonance. The second inner conductor 515 may be coupled (e.g., capacitive coupled) to the first inner conductor 513, and through this coupling relationship, when the electric field is generated in the first region, the induced electric field may also be formed in the second region. In the disclosure, the “capacitive coupling” may denote a coupling relationship in which energy may be transmitted through a capacitance between two conductors.

For example, as the microwaves generated from the source unit 500 are transmitted to the first inner conductor 513, the electric field may be generated in the first region through resonance, and the induced electric field may be generated in the second region formed by the outer conductor 511 and the second inner conductor 515 coupled to the first inner conductor 513.

According to an embodiment, the first region and the second region of the resonating unit 510 may operate as the resonators having a ¼ wavelength (λ) of the microwaves.

For example, an end (e.g., an end in a −y direction) of the first region may be formed as the short end, as a cross-section of the first region is closed by the first surface 511a of the outer conductor 511, and another end (e.g., an end in a +y direction) of the first region may be formed as the open end, as a cross-section thereof is open because the first surface 511a is not arranged.

As another example, an end (e.g., an end in the −y direction) of the second region may be formed as the open end as a cross-section of the second region is open, and another end (e.g., an end in the +y direction) of the second region may be formed as the short end as a cross-section thereof is closed by the second surface 511b of the outer conductor 511.

That is, on a y-z plane, the first region and the second region may be formed to generally have a “⊏” shape including the short end and the open end, and through this structure, each of the first region and the second region may operate as the resonator having the ¼ wavelength of the microwaves.

According to an embodiment, the first inner conductor 513 and the second inner conductor 515 may be formed to have the same length as each other with respect to a y axis, so that the first region and the second region may be arranged to be symmetrical with each other, but the disclosure is not limited thereto.

The aerosol generating article 2 inserted into the inner space of the outer conductor 511 through the accommodation space 510h may be surrounded by the first inner conductor 513 and the second inner conductor 515 and heated by a dielectric heating method.

At least a portion of the electric field generated through the microwave resonance in the first region and/or the second region may propagate toward the inside of the first inner conductor 513 and/or the second inner conductor 515 through the gap 516 between the first inner conductor 513 and the second inner conductor 515, and the aerosol generating article 2 surrounded by the first inner conductor 513 and the second inner conductor 515 may be heated by the propagating electric field. For example, a dielectric included in the aerosol generating article 2 may generate heat through the electric field propagating through the gap 516, and the aerosol generating article 2 may be heated by the heat generated from the dielectric.

In the heater assembly 50 according to an embodiment, diameters of the first inner conductor 513 and the second inner conductor 515 may have a value less than a predetermined value, and thus, the electric field propagating toward the inside of the first inner conductor 513 and/or the second inner conductor 515 may be prevented from being leaked to the outside of the heater assembly 50 or the resonating unit 510.

In the disclosure, the “predetermined value” may denote a diameter value at which the electric field starts to be leaked to the outside of the first inner conductor 513 and/or the second inner conductor 515. For example, when the diameter of the first inner conductor 513 and/or the second inner conductor 515 is the predetermined value or greater, a portion of the electric field introduced into the first inner conductor 513 and/or the second inner conductor 515 may leak to the outside of the resonating unit 510.

On the contrary, through the structure in which the diameter of the first inner conductor 513 and the second inner conductor 515 is less than the predetermined value, the heater assembly 50 may prevent the propagation of the electric field to the outside of the resonating unit 510. As a result, leakage of the electric field to the outside of the heater assembly 50 or the resonating unit 510 may be prevented without an additional shielding member.

According to an embodiment, when the aerosol generating article 2 is inserted into the resonating unit 510 through the accommodation space 510h, the aerosol generating rod 21 of the aerosol generating article 2 may be arranged in a position corresponding to the gap 516 between the first inner conductor 513 and the second inner conductor 515.

As the electric field generated in the first region and the electric field generated in the second region are introduced into the first inner conductor 513 and/or the second inner conductor 515 through the gap 516, the most intense electric field may be generated in a peripheral region of the gap 516 in the resonating unit 510.

In the heater assembly 50 according to an embodiment, the aerosol generating rod 21 including a dielectric that generates heat through an electric field, may be arranged in the position corresponding to the gap 516, at which the electric field is the most intense. Thus, the heating efficiency (or the “dielectric heating efficiency”) of the heater assembly 50 may be improved.

According to an embodiment, the resonating unit 510 may further include a closing unit 514 positioned in the first inner conductor 513 and configured to close a cross-section of the first inner conductor 513 to limit a flow direction of aerosols generated from the aerosol generating article 2. For example, the closing unit 514 may close the cross-section of the first inner conductor 513, thereby blocking the flow of the aerosols generated from the aerosol generating article 2 in the-y direction.

When the aerosols generated from the aerosol generating article 2 or droplets generated when the aerosols are liquefied flow in the-y direction and are introduced to other components of an aerosol generating device (e.g., the aerosol generating device 1 of FIGS. 1 and 2), malfunction or damage to the components of the aerosol generating device may be caused. However, in the heater assembly 50 according to an embodiment, the flow direction of the aerosols is limited through the closing unit 514, and thus, malfunction or damage to the components of the aerosol generating device, caused by the aerosols or the droplets, may be prevented.

According to an embodiment, the resonating unit 510 may further include a dielectric accommodation space 517. The dielectric accommodation space 517 may be a separate component from the accommodation space 510h for the aerosol generating article 2. In the dielectric accommodation space 517, a material for changing the resonance frequency of the entire resonating unit 510 may be arranged to miniaturize the resonating unit 510. According to an embodiment, a dielectric having a low degree of microwave absorption may be accommodated in the dielectric accommodation space 517. This may be configured to prevent generation of heat directly in the dielectric with the energy, which is originally to be transmitted to an object of heating, being transmitted to the dielectric. The degree of microwave absorption may be represented by a loss tangent, which is a ratio of an imaginary part to a real part in a complex dielectric constant. According to an embodiment, a dielectric having the loss tangent of a predetermined size or less may be accommodated in the dielectric accommodation space 517, wherein the predetermined size may be 1/100. For example, the dielectric may include at least one or a combination of quartz, tetrafluorethylene, and aluminum oxide, but is not limited thereto.

In the heater assembly 50 according to an embodiment, the dielectric may be arranged in the dielectric accommodation space 517, and thus, while the resonating unit 510 may have a reduced size overall, an electric field the same as the electric field generated in the resonating unit 510 not including the dielectric may be generated in the resonating unit 510. That is, in the heater assembly 50 according to an embodiment, through the dielectric arranged in the dielectric accommodation space 517, the size of the resonating unit 510 may be reduced, so that a mounting space of the resonating unit 510 in an aerosol generating device may be reduced, and accordingly, the aerosol generating device may be miniaturized.

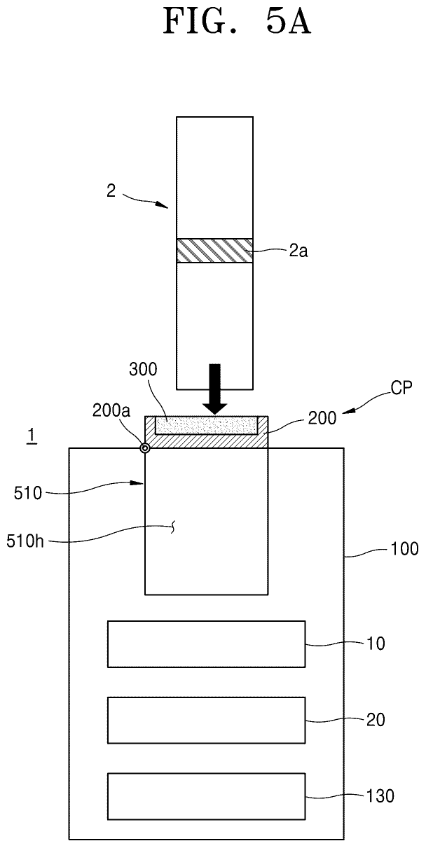

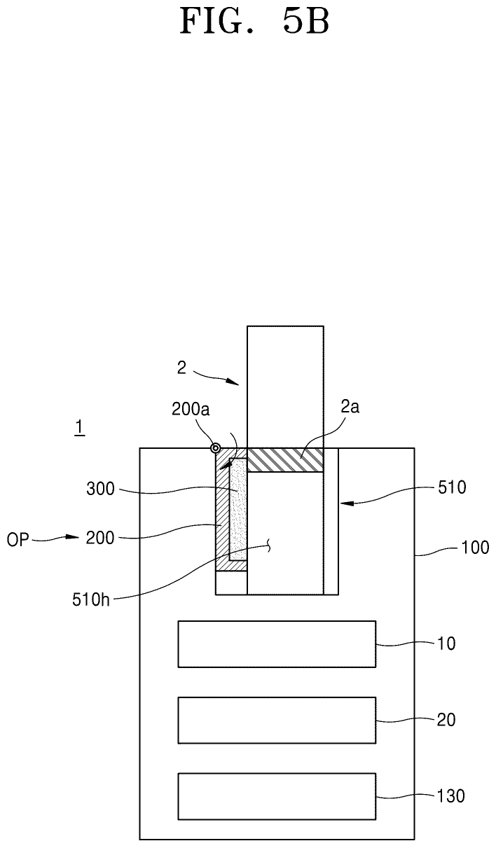

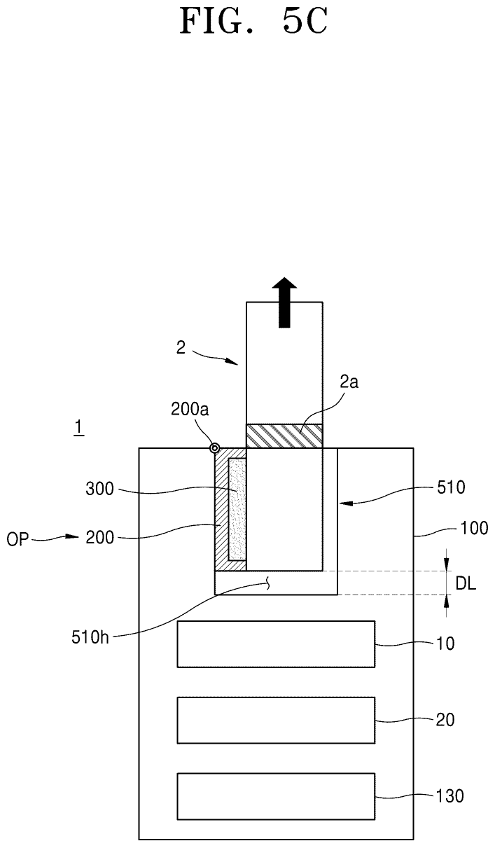

FIG. 5A is a side view illustrating the aerosol generating article 2 before being inserted into the aerosol generating device 1 including the cover 200 according to an embodiment, and FIG. 5B is a side view illustrating the aerosol generating article 2 completely inserted into the aerosol generating device 1 including the cover 200 according to an embodiment. FIG. 5C is a side view illustrating the aerosol generating article 2 detached from the aerosol generating device 1 including the cover 200 according to an embodiment.

Referring to FIGS. 5A to 5C, the aerosol generating device 1 may include the control unit 10, the source unit 20, the housing 100, the power supply 130, the cover 200, a detection sensor 300, the resonating unit 510, and the accommodation space 510h. At least one (for example, the source unit 20) of the components of the aerosol generating device 1 of FIGS. 5A to 5C is described above, and redundant descriptions are omitted hereinafter.

According to an embodiment, the control unit 10 may control the source unit 20, based on an external force applied to the cover 200 by the aerosol generating article 2. When the aerosol generating device 1 detects a detachment of the aerosol generating article 2, the control unit 10 may control, based on the detection, the source unit 20 to block generation of microwaves.

The cover 200 may be rotatably arranged in the housing 100. The cover 200 may be arranged to be rotatable between a closing position CP (illustrated in FIG. 5A) to close the accommodation space 510h and an opening position OP (illustrated in FIGS. 5B and 5C) to open the accommodation space 510h. For example, the cover 200 may be rotatably arranged in the housing 100 through a hinge 200a coupled to each of the housing 100 and the cover 200.

In the disclosure, the closing position CP may be a position of the cover 200 for making the accommodation space 510h surrounded and completely sealed by the cover 200 and the housing 100. Also, the opening position CP may be a position of the cover 200 for making at least a portion of the accommodation space 510h open through a space between the cover 200 and the housing 100.

Although not shown, the aerosol generating device 1 may further include a restoring unit. The restoring unit may apply an elastic force to the cover 200 so that the cover 200 may move from the opening position OP to the closing position CP. Accordingly, when the aerosol generating article 2 is completely detached from the accommodation space 510h, the cover 200 may automatically move to the closing position CP from the opening position OP through the restoring unit. For example, the restoring unit may include a spring. The restoring unit may be coupled to the hinge 200a by being wound. However, the coupling method is not limited thereto and may include any method of applying an elastic force to the cover 200.

The detection sensor 300 may detect the detachment of the aerosol generating article 2. When, while the aerosol generating article 2 is being accommodated in the accommodation space 510h, an external force is applied to the detection sensor 300 in a direction in which the aerosol generating article 2 is detached from the accommodation space 510h, the detection sensor 300 may output a signal corresponding to a detachment of the aerosol generating article 2, and the control unit 10 may determine the detachment of the aerosol generating article 2, based on the output signal.

Also, the detection sensor 300 may detect an insertion of the aerosol generating article 2. When, while the aerosol generating article 2 is being accommodated in the accommodation space 510h, an external force is applied to the detection sensor 300 in a direction in which the aerosol generating article 2 faces the accommodation space 510h, the detection sensor 300 may output a signal corresponding to an insertion of the aerosol generating article 2, and the control unit 10 may determine the insertion of the aerosol generating article 2, based on the output signal.

That is, the detection sensor 300 may detect the detachment or the insertion of the aerosol generating article 2, based on the direction in which the external force is applied to the cover 200 by the aerosol generating article 2.

According to an embodiment, the detection sensor 300 may include a piezoelectric device. In the disclosure, the piezoelectric device may be configured to convert physical pressure into an electrical signal by using a piezoelectric effect. When an external force is applied to the detection sensor 300, which is the piezoelectric device, electric polarization may occur in the piezoelectric device, and as a result, the piezoelectric device itself may form an electric field to generate currents.

That is, when a physical external force is applied to the detection sensor 300, which is the piezoelectric device, a polarization phenomenon may be induced, and as a result, currents may start to flow to the detection sensor 300 (voltages may be generated in the detection sensor 300), and thus, power may be generated. The power generated by the detection sensor 300 may have a range of microwatts (μW) to milliwatts (mW). An external force needed by the piezoelectric device to generate power may be about 10 kN, but is not limited thereto.

For example, the piezoelectric device may mainly include at least one crystalline material from ceramics and quartz.

Although not shown, the detection sensor 300 may include a first electrode, a second electrode, a sensing layer, and a substrate. Here, the substrate, the first electrode, the sensing layer, and the second electrode may be sequentially stacked.

When an external force is not applied to the detection sensor 300, charges may be arranged in the sensing layer without directionality. As a result, the first electrode and the second electrode may not be electrified so as to be maintained in an electrically neutral state, and the detection sensor 300 may not generate currents.

Here, when an external force is applied to the detection sensor 300, a polarization phenomenon may be induced due to charges in the sensing layer. In detail, when a portion (e.g., the second electrode) of the detection sensor 300 is pressurized, the sensing layer may also be pressurized, and as a result, the polarization phenomenon may be induced in the detection sensor 300 due to the charges in the sensing layer.

For example, when an external force is applied to the detection sensor 300, the charges may be arranged to have a specific directionality, for example, negative (−) charges may be biased toward the first electrode, and positive (+) charges may be biased toward the second electrode. As a result, the first electrode may be electrified to a negative (−) electrode, and the second electrode may be electrified to a positive (+) electrode, so that the detection sensor 300 may directly form an electric field, and currents may flow to the detection sensor 300. Through this process, the detection sensor 300 may generate currents by using an external force, which is mechanical energy, and may generate electrical energy.

However, the electrified states of the first electrode and the second electrode are only an example. According to an embodiment, the first electrode may be electrified to a positive (+) electrode, and the second electrode may be electrified to a negative (−) electrode.

According to an embodiment, as the external force applied to the detection sensor 300 increases, sizes of currents and power generated by the detection sensor 300 may increase.

The first electrode, the second electrode, and the sensing layer may be arranged on the substrate. For example, the substrate may include a silicon substrate or a silicon thin film for generating a semiconductor device or an integrated circuit (IC). As another example, the substrate may include a printed circuit board (PCB) or a flexible printed circuit board (FPCB). However, the substrate may include substrates including other materials capable of performing the same function as described above.

For example, the substrate may include a metal material. In this case, an insulating layer may be formed between the first electrode and the substrate to prevent electrical contact therebetween. An insulating layer may denote an additional layer formed by using an insulating material to prevent transmission of electricity or heat. The insulating layer described above may correspond to an oxide layer or a nitride layer formed by stacking silicon oxide (SiO₂) or silicon nitride (Si₃N₄) on the substrate.

As another example, the substrate may include an insulator. In this case, the first electrode may be directly deposited on the substrate.

However, a structure of the detection sensor 300 is not limited to the structure described above. The structure of the detection sensor 300 may include other changed forms that generate currents by using mechanical energy and generate electrical energy.

According to an embodiment, the detection sensor 300 may be arranged in the cover 200. The detection sensor 300 may be arranged on a surface of the cover 200 to be in contact with the aerosol generating article 2 accommodated in the accommodation space 510h. That is, at least a portion of the detection sensor 300 may be exposed to the outside of the cover 200. When the aerosol generating article 2 is inserted into the accommodation space 510h, the detection sensor 300 may be exposed to the outside of the cover 200 to face the aerosol generating article 2.

The detection sensor 300 may be electrically connected to the components of the aerosol generating device 1. For example, the detection sensor 300 may be electrically connected to at least one of the control unit 10 or the power supply 130.

A length of the detection sensor 300 may be the same as a length of the cover 200. Thus, an area in which the detection sensor 300 may detect the aerosol generating article 2 may increase, and thus, the control unit 10 may easily determine a detachment or an insertion of the aerosol generating article 2.

Referring to FIGS. 5A to 5C, the aerosol generating article 2 may include a shielding unit 2a.

The shielding unit 2a may prevent microwaves generated by the source unit 20 from leaking to the outside of the aerosol generating article 2 through the aerosol generating article 2. That is, the microwaves generated by the source unit 20 may be transferred to an inner space of the resonating unit 510, and the microwaves may be transferred to the outside of the aerosol generating article 2 through the aerosol generating article 2 accommodated in the accommodation space 510h. The shielding unit 2a may prevent the leakage of the microwaves through the aerosol generating article 2, and thus, the safety of use for an aerosol generating system may be improved.

The shielding unit 2a may be arranged in the aerosol generating article 2. A diameter of the shielding unit 2a may be equal to or less than a diameter of the aerosol generating article 2.

The shielding unit 2a may include a shielding material including metal. The shielding material may include an electrically conductive material or a thermally conductive material and may include, for example, at least one of an aluminum material or a stainless steel material.

According to an embodiment, the shielding unit 2a may include a mesh structure. In the disclosure, the mesh structure may include a structure for blocking microwaves and having a plurality of holes for transmitting air or aerosols.

A size of a mesh hole may be determined by a frequency (or a wavelength) of the microwaves generated by the source unit 20. In detail, the size of the hole may be configured to be less than ⅓ of a wavelength of the microwaves generated by the source unit 20. For example, the wavelength of the microwaves having a frequency of 2.45 GHz is about 120 mm, and thus, a diameter of the hole may be configured to be less than 40 mm.

Hereinafter, an embodiment is described, in which the control unit 10 may control the source unit 20 and the power supply 130 in a process in which the aerosol generating article 2 is accommodated in the accommodation space 510h and detached from the accommodation space 510h.

First, as illustrated in FIG. 5A, while the aerosol generating article 2 is being detached from the aerosol generating device 1, the aerosol generating article 2 may start to move to the accommodation space 510h. After the aerosol generating article 2 contacts the cover 200 positioned at the closing position CP, the aerosol generating article 2 may push and rotate the cover 200. Thus, the cover 200 may rotate with respect to the hinge 200a, and at least a portion of the accommodation space 510h may be open.

For example, when the aerosol generating device 1 is in an off state, the detection sensor 300 may not operate even when the aerosol generating article 2 is in contact with the cover 200, and may not detect an insertion of the aerosol generating article 2.

As another example, when the aerosol generating device 1 is in an on state, the detection sensor 300 may operate when the aerosol generating article 2 is in contact with the cover 200 and may detect an insertion of the aerosol generating article 2.

Next, as illustrated in FIG. 5B, the cover 200 may rotate with respect to the hinge 200a, thereby moving to the opening position OP. When the aerosol generating article 2 is completely accommodated in the accommodation space 510h, the control unit 10 may control the source unit 20 to output microwaves. To this end, the control unit 10 may control power supplied from the power supply 130 to the source unit 20.

When the aerosol generating article 2 is completely accommodated in the accommodation space 510h, the shielding unit 2a may be positioned at the same position as an upper surface of the housing 100. Thus, in a direction in which the housing 100 extends, a distance may not be formed between the upper surface of the housing 100 and the shielding unit 2a. Thus, the blocking power for blocking the leakage of the microwaves generated by the source unit 20 through a space between the housing 100 and the shielding unit 2a may be improved.

Next, as illustrated in FIG. 5C, the aerosol generating article 2 may be detached from the accommodation space 510h. While the source unit 20 is operating, the aerosol generating article 2 may be detached from the aerosol generating device 1 due to user's selection or a user's mistake. In this case, the microwaves may leak to the outside of the aerosol generating device 1 through the accommodation space 510h.

According to an embodiment, when an external force is applied to the cover 200 in a direction in which the aerosol generating article 2 is detached from the accommodation space 510h, the external force may be sequentially applied to the detection sensor 300, and the detection sensor 300 may detect a detachment of the aerosol generating article 2. In this case, the control unit 10 may control the source unit 20 to block generation of the microwaves. Thus, even when the aerosol generating article 2 is detached from the aerosol generating device 1 due to user's selection or a user's mistake, the microwaves may not leak to the outside of the aerosol generating device 1 through the accommodation space 510h. Therefore, the safety of use for the aerosol generating device 1 may be improved.

According to an embodiment, when the aerosol generating article 2 is detached from the accommodation space 510h by a preconfigured range or greater, the control unit 10 may control the source unit 20 to block the generation of the microwaves. Here, the preconfigured range may be a distance DL (illustrated in FIG. 5C) between a bottom surface of the accommodation space 510h and a lower surface of the aerosol generating article 2. During smoking, regardless of a user's intention, a situation may occur in which an external force is applied to the cover 200 in a direction in which the aerosol generating article 2 is detached from the accommodation space 510h. When the control unit 10 blocks the generation of the microwaves also in this case, inconvenience of use for the aerosol generating device 1 may occur. In the aerosol generating device 1 according to an embodiment, the generation of the microwaves is blocked only when the aerosol generating article 2 is detached from the accommodation space 510h by the preconfigured range or greater, and thus, the safety and convenience of use for the aerosol generating device 1 may be achieved.

For example, when the aerosol generating article 2 applies an external force to the cover 200 for a preconfigured time period of longer, the detection sensor 300 may detect that the aerosol generating article 2 is detached from the accommodation space 510h by the preconfigured range or greater. Here, the preconfigured time period (e.g., 1.5 secs) may be pre-input in a memory and may be changed according to user's selection.

As another example, the aerosol generating device 1 may include an additional movement detection sensor configured to detect a detachment of the aerosol generating article 2 from the accommodation space 510h by the preconfigured range or greater. The movement detection sensor may be positioned within a preconfigured range from the bottom surface of the accommodation space 510h.

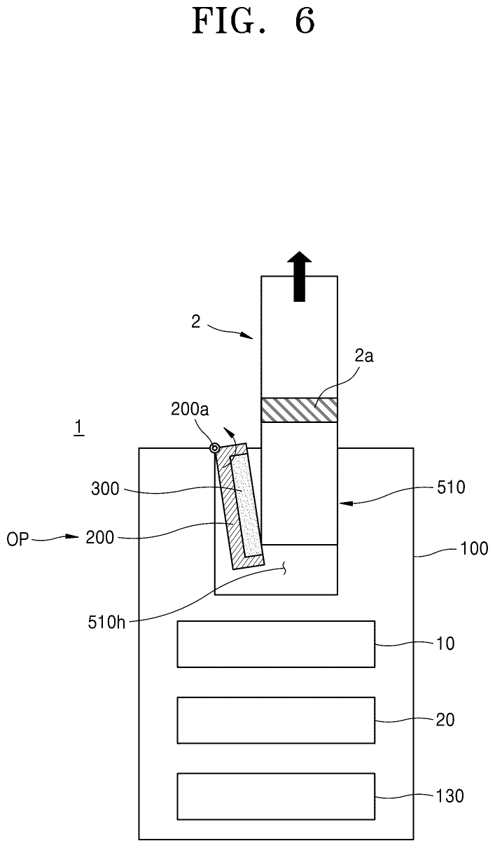

FIG. 6 is a side view illustrating another shape of the aerosol generating article 2 detached from the aerosol generating device 1 including the cover 200, according to an embodiment.

Referring to FIG. 6, the aerosol generating device 1 may include the control unit 10, the source unit 20, the housing 100, the power supply 130, the cover 200, the detection sensor 300, the resonating unit 510, and the accommodation space 510h. At least one (for example, the detection sensor 300) of the components of the aerosol generating device 1 of FIG. 6 is described above, and redundant descriptions are omitted hereinafter.

According to an embodiment, the control unit 10 may control the source unit 20, based on movement of the cover 200. That is, when the cover 200 is completely open (the state illustrated in FIG. 5B), and when the cover 200 starts to move as the aerosol generating article 2 is detached, the control unit 10 may control the source unit 20 to block generation of microwaves.

Thus, even when the detection sensor 300 is broken or there is no detection sensor 300, microwaves may not leak to the outside of the aerosol generating device 1 through the accommodation space 510h, when the aerosol generating article 2 is detached from the aerosol generating device 1. Therefore, the safety of use for the aerosol generating device 1 may further be improved.

Although not shown, the aerosol generating device 1 may further include a microwave recognition sensor.

The microwave recognition sensor may detect microwaves generated by the source unit 20. The microwave recognition sensor may be arranged in the housing 100 to be exposed toward the accommodation space 510h.

For example, the microwave recognition sensor may include a capacitance sensor. When the microwaves leak to the accommodation space 510h, a dielectric constant in the accommodation space 510h may change. Here, the microwave recognition sensor may detect a change in dielectric constant, and the control unit 10 may detect the microwaves, based on a signal corresponding to the dielectric constant, etc. in the accommodation space 510h, the signal being output from the capacitance sensor.

At the opening position OP (illustrated in FIG. 5B) at which the aerosol generating article 2 is completely accommodated in the accommodation space 510h, the microwave recognition sensor may be positioned in the housing 100 to be covered by the cover 200. Here, even when the microwaves leak to the accommodation space 510h, the microwave recognition sensor may not detect the microwaves.

At the opening position OP at which the cover 200 is completely open, when the cover 200 starts to move as the aerosol generating article 2 is detached, a space may be formed between the cover 200 and an inner surface of the housing 100 facing the accommodation space 510h. Here, the microwave recognition sensor may recognize the leaking microwaves, through the space, and the control unit 10 may control the source unit 20 to block generation of the microwaves.

Thus, even when the detection sensor 300 is broken or there is no detection sensor 300, the microwaves may not leak to the outside of the aerosol generating device 1 through the accommodation space 510h, when the aerosol generating article 2 is detached from the aerosol generating device 1. Therefore, the safety of use for the aerosol generating device 1 may further be improved.

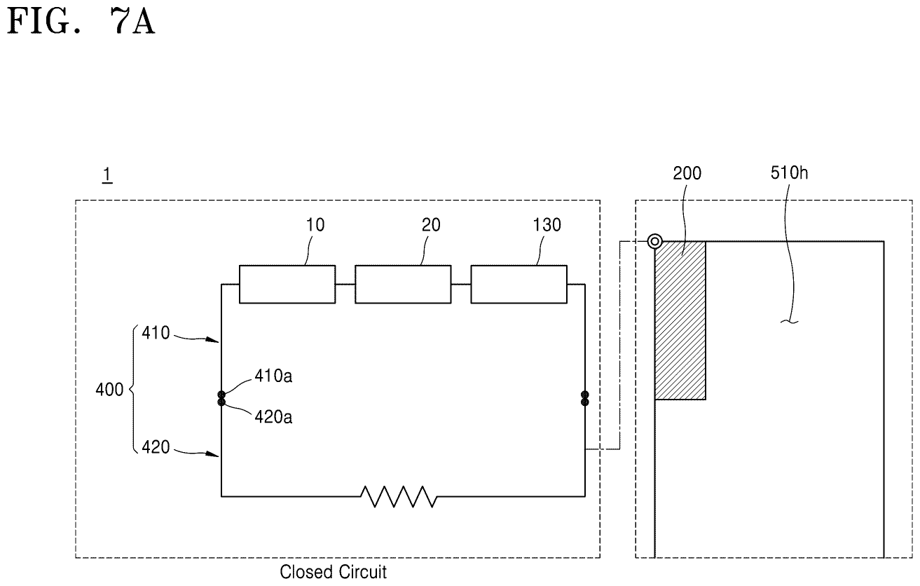

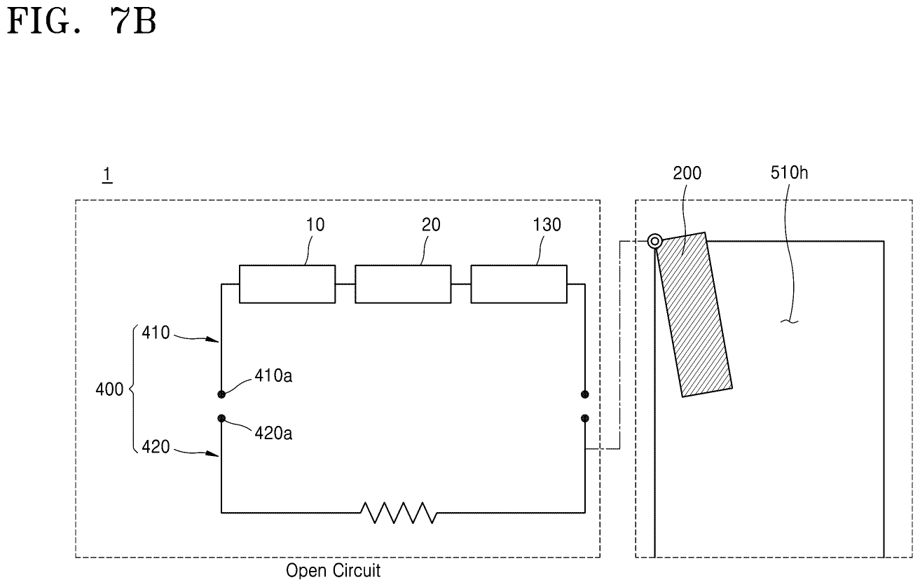

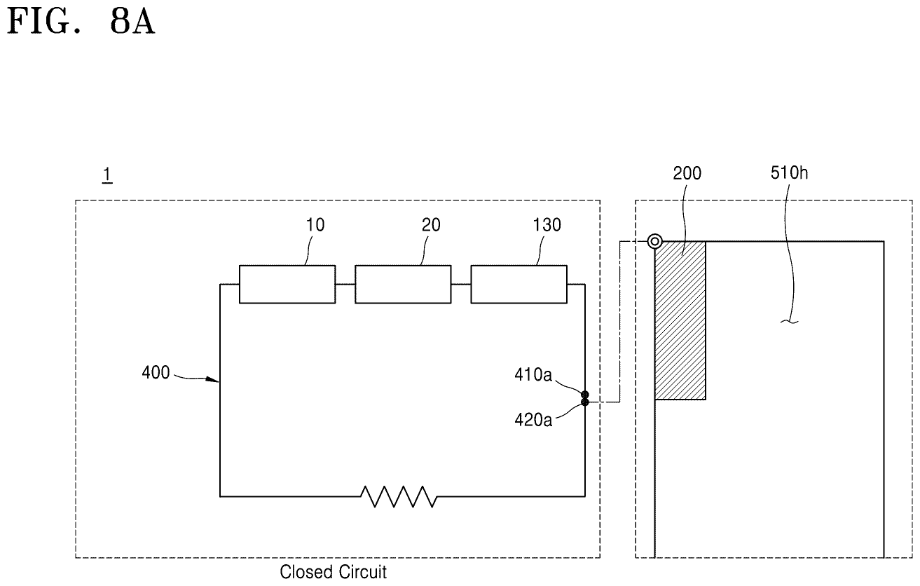

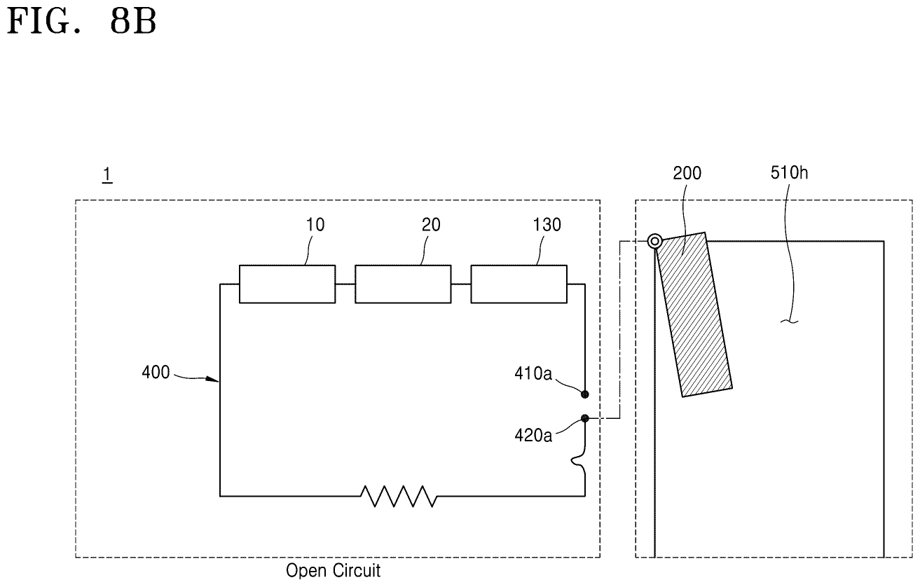

The structure in which the control unit 10 controls the source unit 20 to block the generation of the microwaves, based on the movement of the cover 200, is described in detail with reference to FIGS. 7A to 8B hereinafter.

FIG. 7A illustrates a connecting circuit 400 in a closed-circuit state, according to an embodiment, and FIG. 7B illustrates the connecting circuit 400 in an open-circuit state, according to an embodiment.

Referring to FIGS. 7A and 7B, the aerosol generating device 1 may include the control unit 10, the source unit 20, the power supply 130, the cover 200, the connecting circuit 400, and the accommodation space 510h. At least one (for example, the accommodation space 510h) of the components of the aerosol generating device 1 of FIGS. 7A and 7B is described above, and redundant descriptions are omitted hereinafter.

The connecting circuit 400 may electrically connect the control unit 10, the source unit 20, and the power supply 130 with each other. The connecting circuit 400 may be positioned in the housing 100 (see FIG. 6) and may be connected to the cover 200. In the disclosure, a “circuit” may denote a system configured for inter-operations of electrical/electronic devices (the control unit, the source unit, etc.) based on power supplied from the power supply 130. The connecting circuit 400 may include a power supply 130, loads (the control unit 10 and the source unit 20), and a conductor.

The connecting circuit 400 may include a fixed circuit 510 and a moving circuit 420.

The fixed circuit 410 may have a fixed position in the housing. The control unit 10, the source unit 20, and the power supply 130 may be connected to the fixed circuit 410. The fixed circuit 410 may include a fixed contact point 410a to be electrically connected to the moving circuit 420.

The moving circuit 420 may move together according to movement of the cover 200 in the housing. The moving circuit 420 may be connected to the cover 200 through a mechanical device. The mechanical device may include a cam configured to induce movement of the moving circuit 420 by using rotation of the cover 200. The moving circuit 420 may include a moving contact point 420a to be electrically connected to the fixed contact point 410a of the fixed circuit 410.

However, unlike the illustrations of FIGS. 7A and 7B, the control unit 10, the source unit 20, and the power supply 130 may be connected to the moving circuit 420, according to an embodiment.

According to an embodiment, the connecting circuit 400 may switch between an open circuit and a closed circuit, based on the movement of the cover 200.

For example, as illustrated in FIG. 7A, at the opening position of the cover 200, at which the aerosol generating article is completely accommodated in the accommodation space 510h, the connecting circuit 400 may become the closed circuit. At the closed circuit, the fixed contact point 410a and the moving contact point 420a may be connected to each other, and thus, the fixed circuit 410 and the moving circuit 420 may be electrically connected to each other. Thus, power supplied from the power supply 130 may be supplied to the components of the aerosol generating device 1, and the control unit 10 may control the source unit 20 to normally output microwaves.

As another example, as illustrated in FIG. 7B, when the cover 200 starts to move to the closing position, as the aerosol generating article is detached from the accommodation space 510h by a preconfigured range, the connecting circuit 400 may become the open circuit. At the open circuit, the fixed contact point 410a and the moving contact point 420a may be separated from each other, and thus, the fixed circuit 410 and the moving circuit 420 may not be electrically connected to each other. Thus, power supplied from the power supply 130 may not be supplied to the components of the aerosol generating device 1, and the control unit 10 may not control the source unit 20 to normally output microwaves.

FIG. 8A illustrates the connecting circuit 400 in a closed-circuit state, according to another embodiment, and FIG. 8B illustrates the connecting circuit 400 in an open-circuit state, according to another embodiment.

Referring to FIGS. 8A and 8B, the aerosol generating device 1 may include the control unit 10, the source unit 20, the power supply 130, the cover 200, the connecting circuit 400, and the accommodation space 510h. At least one (for example, the accommodation space 510h) of the components of the aerosol generating device 1 of FIGS. 8A and 8B is described above, and redundant descriptions are omitted hereinafter.

The connecting circuit 400 may electrically connect the control unit 10, the source unit 20, and the power supply 130 with each other. The connecting circuit 400 may be positioned in the housing 100 (see FIG. 6) and may be connected to the cover 200.

The connecting circuit 400 may have a fixed position in the housing. The control unit 10, the source unit 20, and the power supply 130 may be connected to the connecting circuit 400. The connecting circuit 400 may include the fixed contact point 410a and the moving contact point 420a moving together according to movement of the cover 200. The moving contact point 420a may be connected to the cover 200 through a mechanical device. The mechanical device may include a cam configured to induce movement of the moving contact point 420a by using rotation of the cover 200.

According to an embodiment, the connecting circuit 400 may switch between an open circuit and a closed circuit, based on the movement of the cover 200.

For example, as illustrated in FIG. 8A, at the opening position of the cover 200, at which the aerosol generating article is completely accommodated in the accommodation space 510h, the connecting circuit 400 may switch to the closed circuit. At the closed circuit, the fixed contact point 410a and the moving contact point 420a may be connected to each other. Thus, power supplied from the power supply 130 may be supplied to the components of the aerosol generating device 1, and the control unit 10 may control the source unit 20 to normally output microwaves.

As another example, as illustrated in FIG. 8B, when the cover 200 starts to move to the closing position, as the aerosol generating article is detached from the accommodation space 510h by a preconfigured range, the connecting circuit 400 may switch to the open circuit. At the open circuit, the fixed contact point 410a and the moving contact point 420a may be separated from each other. Thus, power supplied from the power supply 130 may not be supplied to the components of the aerosol generating device 1, and the control unit 10 may not control the source unit 20 to normally output microwaves.

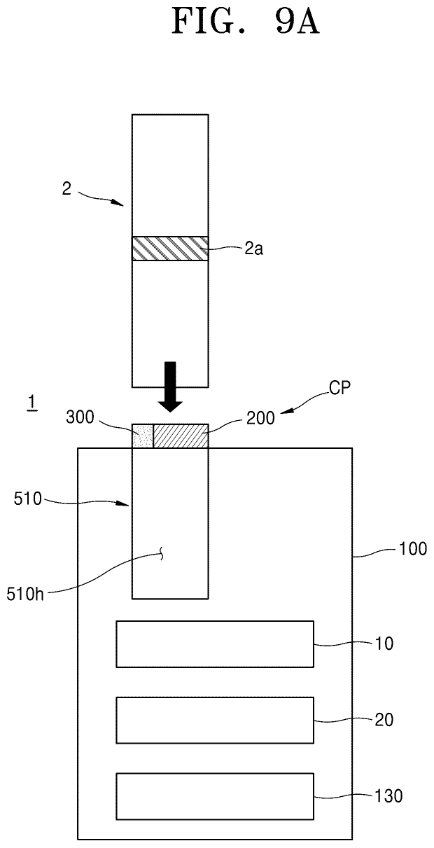

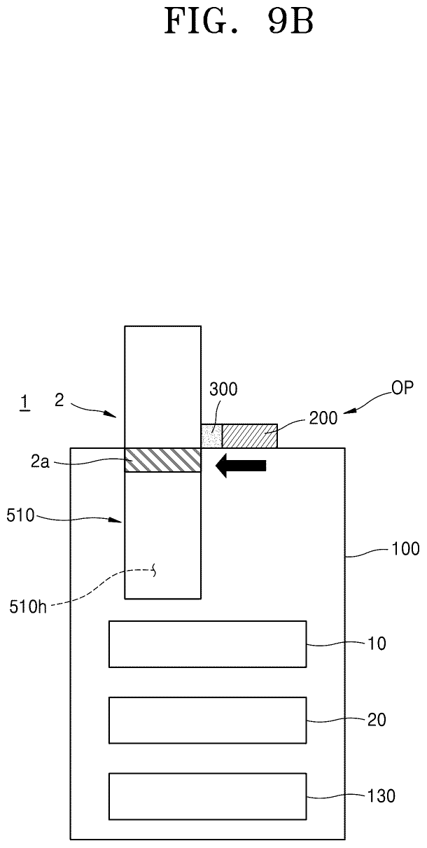

FIG. 9A is a side view illustrating the aerosol generating article 2 before being inserted into the aerosol generating device 1 including the cover 200, according to another embodiment, and FIG. 9B is a side view illustrating the aerosol generating article 2 completely inserted into the aerosol generating device 1 including the cover 200, according to another embodiment.

Referring to FIGS. 9A and 9B, the aerosol generating device 1 may include the control unit 10, the source unit 20, the housing 100, the power supply 130, the cover 200, the detection sensor 300, the resonating unit 510, and the accommodation space 510h. The aerosol generating device 1 of FIGS. 9A and 9B is different from the aerosol generating device 1 of FIG. 8B only in terms of a moving structure of the cover 200. Thus, hereinafter, redundant descriptions are omitted, and different aspects are mainly described.

According to an embodiment, the control unit 10 may control the source unit 20, based on an external force applied to the cover 200 by the aerosol generating article 2. When the detection sensor 300 detects a detachment of the aerosol generating article 2, the control unit 10 may control, based on the detection operation of the detection sensor 300, the source unit 20 to block generation of microwaves.

The cover 200 may be slidably arranged in the housing 100. The cover 200 may be arranged to be slidable between the closing position CP (illustrated in FIG. 9A) to close the accommodation space 510h and the opening position OP (illustrated in FIG. 9B) to open the accommodation space 510h. For example, the cover 200 may slidingly move on an upper surface of the housing 100.

Although not shown, the aerosol generating device 1 may further include a restoring unit. The restoring unit may apply an elastic force to the cover 200 so that the cover 200 may move from the opening position OP to the closing position CP. Accordingly, when the aerosol generating article 2 is completely detached from the accommodation space 510h, the cover 200 may automatically move to the closing position CP from the opening position OP through the restoring unit. Also, when the aerosol generating article 2 is completely inserted into the accommodation space 510h, the cover 200 may always be in contact with the aerosol generating article 2 through the restoring unit. The restoring unit may be connected to each of the housing 100 and the cover 200.

The detection sensor 300 may detect the detachment of the aerosol generating article 2. When, while the aerosol generating article 2 is being accommodated in the accommodation space 510h, an external force is applied to the detection sensor 300 in a direction in which the aerosol generating article 2 is detached from the accommodation space 510h, the detection sensor 300 may output a signal corresponding to a detachment of the aerosol generating article 2, and the control unit 10 may determine the detachment of the aerosol generating article 2, based on the output signal.

According to an embodiment, the detection sensor 300 may include a piezoelectric device.

According to an embodiment, the detection sensor 300 may be arranged in the cover 200. The detection sensor 300 may be arranged on a surface of the cover 200 to be in contact with the aerosol generating article 2 accommodated in the accommodation space 510h. That is, at least a portion of the detection sensor 300 may be exposed to the outside of the cover 200. For example, when the aerosol generating article 2 is inserted into the accommodation space 510h, the detection sensor 300 may be exposed to the outside of the cover 200 to face the aerosol generating article 2.

The detection sensor 300 may be electrically connected to the components of the aerosol generating device 1. For example, the detection sensor 300 may be electrically connected to at least one of the control unit 10 or the power supply 130.

A thickness of the detection sensor 300 may be the same as a thickness of the cover 200. Thus, an area in which the detection sensor 300 may detect the aerosol generating article 2 may increase, and thus, the control unit 10 may easily determine the detachment of the aerosol generating article 2.

The aerosol generating article 2 may include the shielding unit 2a.

According to the embodiment illustrated in FIGS. 9A and 9B, a control method performed by the control unit 10 to control the source unit 20 and the power supply 130 in a process in which the aerosol generating article 2 is accommodated in the accommodation space 510h and detached from the accommodation space 510h, may be the same as that of the embodiment illustrated in FIGS. 5A to 5C. Thus, redundant descriptions are omitted.

Certain embodiments or other embodiments of the disclosure described above are not exclusive or distinct from each other. The certain embodiments or other embodiments of the disclosure described above may be combined with each other or used in combination with each other in their respective components or functions.

For example, it means that an A component described in a specific embodiment and/or the drawings and a B component described in another embodiment and/or the drawings may be combined with each other. In other words, even when it is not explained directly about combination between components, it is possible to combine unless it is explained that combination is impossible.

The above detailed description should not be interpreted restrictedly and should be considered as exemplary in all aspects. The scope of the disclosure should be determined by a rational interpretation of the attached claims, and all changes within the equivalent scope of the disclosure are included in the scope of the disclosure.

According to various embodiments, when a detachment of an aerosol generating article is detected, leakage of microwaves or electromagnetic waves to the outside may be prevented, and thus, the safety of use for an aerosol generating device may be improved.

Effects according to the spirit of the present disclosure are not limited to the above-mentioned effects, and other effects not mentioned will be clearly understood by those skilled in the art from the following description.

What is claimed is:

1. An aerosol generating device comprising:
a source unit configured to generate microwaves;
a resonating unit comprising an accommodation space for accommodating an aerosol generating article and configured to generate microwave resonance due to the microwaves generated by the source unit;
a cover arranged in the resonating unit to move between an opening position to open the accommodation space and a closing position to close the accommodation space; and
a control unit configured to control the source unit based on an external force applied by the aerosol generating article to the cover.

2. The aerosol generating device of claim 1, wherein, when the aerosol generating article applies the external force to the cover in a direction in which the aerosol generating article is detached from the accommodation space, the control unit is configured to control the source unit to block the generation of the microwaves.

3. The aerosol generating device of claim 1, further comprising a detection sensor arranged in the cover and configured to detect a detachment of the aerosol generating article from the accommodation space.

4. The aerosol generating device of claim 3, wherein the detection sensor is arranged on a surface of the cover to be in contact with the aerosol generating article accommodated in the accommodation space.

5. The aerosol generating device of claim 3, wherein the detection sensor comprises a piezoelectric device configured to generate current when pressurized by the aerosol generating article.

6. The aerosol generating device of claim 1, further comprising a restoring unit configured to apply an elastic force to the cover to move from the opening position to the closing position.

7. The aerosol generating device of claim 1, wherein the cover is arranged to rotate between the opening position and the closing position.

8. The aerosol generating device of claim 1, wherein the cover is arranged to slide between the opening position and the closing position.

9. The aerosol generating device of claim 1, further comprising:
a power supply configured to supply power to the source unit; and
a connecting circuit configured to connect the power supply to the source unit,
wherein the connecting circuit switches between an open circuit and a closed circuit based on movement of the cover.

10. The aerosol generating device of claim 9, wherein at the opening position of the cover at which the aerosol generating article is completely accommodated in the accommodation space the connecting circuit switches to the closed circuit.

11. The aerosol generating device of claim 9, wherein, when the cover starts to move to the closing position as the aerosol generating article is detached from the accommodation space by a preconfigured range, the connecting circuit switches to the open circuit.

12. The aerosol generating device of claim 9, wherein the connecting circuit comprises a moving circuit moving together with the cover and a fixed circuit electrically connected to the moving circuit.

13. The aerosol generating device of claim 9, wherein the connecting circuit comprises a moving contact point moving together with the cover and a fixed contact point electrically connected to the moving contact point.

14. The aerosol generating device of claim 1, wherein, when the aerosol generating article is detached from the accommodation space by a preconfigured range or greater, the control unit is configured to control the source unit to block the generation of the microwaves.

15. The aerosol generating device of claim 1, wherein, when the aerosol generating article applies the external force to the cover for a preconfigured time period or longer, the control unit is configured to control the source unit to block the generation of the microwaves.
